(19) United States
(12) Patent Application Publication
(10) Pub. No.: US 2025/0174487 A1
(43) Pub. Date: May 29, 2025

(54) SUBSTRATE TRANSFER APPARATUS AND SUBSTRATE PROCESSING APPARATUS INCLUDING THE SAME

(71) Applicant: SCREEN Holdings Co., Ltd., Kyoto (JP)

(72) Inventors: Hiroyuki KAWAHARA, Kyoto (JP); Takashi OTA, Kyoto (JP); Takuya SATO, Kyoto (JP)

(21) Appl. No.: 18/961,835

(22) Filed: Nov. 27, 2024

(30) Foreign Application Priority Data
Nov. 29, 2023 (JP) 2023-202089

(51) Int. Cl. H01L 21/687; H01L 21/677; H01L 21/68

(52) U.S. Cl. CPC H01L 21/68707; H01L 21/67742; H01L 21/68

(57) ABSTRACT

A substrate transfer apparatus includes a hand, a horizontal drive mechanism that advances and retracts the hand, at least two guides, and an advancing/retracting drive mechanism that drives at least one of the at least two guides. The hand has modes for holding the substrate including: an upper holding in which the hand is positioned above the substrate and the guide clamps an outer peripheral surface of the substrate in a state where the hand and the substrate are separated from each other; and a lower holding in which the hand is positioned below the substrate, and the guide clamps an outer peripheral surface of the substrate in a state where the hand and the substrate are separated from each other.

### BACKGROUND OF THE INVENTION

### (1) Field of the Invention

The present invention relates to a substrate transfer apparatus that transfers a substrate such as a semiconductor substrate, a substrate for a flat panel display (FPD) such as a liquid crystal display or an organic electroluminescence (EL) display device, a glass substrate for a photomask, or a substrate for an optical disk, and a substrate processing apparatus including the substrate transfer apparatus.

### (2) Description of the Related Art

Conventionally, as this type of apparatus, there is an apparatus including a carrier that holds a plurality of substrates, a substrate transfer mechanism that unloads a substrate from the carrier and loads the substrate into a substrate processing apparatus, and a control unit that controls the substrate transfer mechanism, in which the control unit changes a height position of a hand when the hand is inserted into the carrier according to a shape of the substrate. For example, Japanese Laid-Open Patent Publication No. 2021-48359 is referred to.

However, the conventional example having such a configuration has the following problems.

That is, the conventional apparatus includes a hand that holds the substrate in the substrate transfer mechanism. Methods of taking the substrate by the hand include an upper holding method in which the hand is brought close to a place where the substrate is placed and the hand takes the substrate from above, and a lower holding method in which the hand takes the substrate from below. Depending on the shape of the substrate and the size of the gap between the substrates placed in the carrier, it is difficult to hold the substrate by any one of the upper holding method and the lower holding method.

In addition, the processing unit that processes the substrate may be determined depending on whether the substrate is loaded or unloaded by the upper holding method or the lower holding method. In such a case, it is necessary to include a substrate transfer mechanism of both the upper holding method and the lower holding method, and to hold the substrate again on the way and load and unload the substrate into and from the processing unit. Therefore, the substrate cannot be efficiently transferred. As a result, there is a problem that the substrate cannot be efficiently processed.

### SUMMARY OF THE INVENTION

The present invention has been made in view of such circumstances, and an object of the present invention is to provide a substrate transfer apparatus capable of efficiently transferring a substrate and a substrate processing apparatus including the same.

In order to achieve such an object, the present invention has the following configuration.

That is, a substrate transfer apparatus according to the present invention includes: a hand that holds the substrate in a horizontal posture; a horizontal drive mechanism that advances and retracts the hand in a horizontal plane in order to deliver the substrate; at least two guides that are provided on the hand and clamp an outer peripheral surface of the substrate to separate and hold the substrate from the hand; and an advancing/retracting drive mechanism that drives at least one of the at least two guides to advance and retract with respect to the substrate as a movable guide, in which the hand has modes for holding the substrate including: an upper holding in which the hand is positioned above the substrate and the guide clamps an outer peripheral surface of the substrate in a state where the hand and the substrate are separated from each other; and a lower holding in which the hand is positioned below the substrate, and the guide clamps an outer peripheral surface of the substrate in a state where the hand and the substrate are separated from each other.

According to the present invention, at least one of at least two guides that clamp the outer peripheral surface of the substrate and hold the substrate separated from the hand is driven to advance and retract with respect to the substrate as a movable guide, so that the substrate is held in a state of being clamped by the guide. Therefore, the substrate transfer apparatus can perform both upper holding and lower holding. As a result, it is possible to provide a substrate transfer apparatus capable of efficiently transferring a substrate.

Further, in the present invention, it is preferable that a plurality of the hands are provided, in which at least one of the plurality of hands is an upper holding hand in which the guide is provided on a lower surface of the hand, and at least one of the plurality of hands is a lower holding hand in which the guide is provided on an upper surface of the hand. Thus, the substrate can be efficiently processed using the two types of hands.

In the present invention, it is preferable that at least one of the upper holding hand and the lower holding hand includes a reverse portion that reverses one surface on which the guide is provided and the other surface on which the guide is not provided. As a result, each hand can perform both upper holding and lower holding.

Further, in the present invention, it is preferable that the hand is a double-sided hand in which the guide is provided on both an upper surface and a lower surface of the hand. As a result, one hand can perform both upper holding and lower holding.

In the substrate transfer apparatus according to the present invention, it is preferable that the double-sided hand includes a reverse portion that reverses the upper surface and the lower surface of the double-sided hand. As a result, the guides provided on the upper surface and the lower surface are used for both upper holding and lower holding.

Further, in the substrate transfer apparatus according to the present invention, it is preferable that the hand includes the guide on one of an upper surface and a lower surface of the hand, and the hand includes a reverse portion that reverses one surface on which the guide is provided and an other surface on which the guide is not provided. As a result, it is possible to perform both upper holding and lower holding only with the guide provided on one surface of the hand.

The present invention also relates to a substrate processing apparatus including: a substrate transfer apparatus that transfers a substrate; a control unit that controls the substrate transfer apparatus; a carrier placement part on which a carrier capable of housing a plurality of substrates stacked with a gap is placed; a temporary placement part on which the substrate unloaded from the carrier placement part is temporarily placed before being loaded into the processing unit; and a processing unit that performs predetermined processing on the substrate loaded from the carrier or the temporary placement part, in which the substrate transfer apparatus includes: a hand that holds the substrate in a horizontal posture; a horizontal drive mechanism that advances and retracts the hand in a horizontal plane in order to deliver the substrate; at least two guides that are provided on the hand and clamp an outer peripheral surface of the substrate to separate and hold the substrate from the hand; and an advancing/retracting drive mechanism that drives at least one of the at least two guides to advance and retract with respect to the substrate as a movable guide, and the hand has modes for holding the substrate including: an upper holding in which the hand is positioned above the substrate and the guide clamps an outer peripheral surface of the substrate in a state where the hand and the substrate are separated from each other; and a lower holding in which the hand is positioned below the substrate, and the guide clamps an outer peripheral surface of the substrate in a state where the hand and the substrate are separated from each other.

According to the present invention, the substrate processing apparatus can efficiently process a substrate using a substrate transfer apparatus that supports both upper holding and lower holding.

Further, in the present invention, it is preferable that the control unit selects either the upper holding or the lower holding with respect to a mode of the hand to be inserted into the carrier or the temporary placement part according to a shape of the carrier or the substrate accommodated in the carrier or the temporary placement part. As a result, the substrate processing apparatus can convey the substrate in the mode of the hand suitable for the shape of the substrate accommodated in the carrier or the temporary placement part.

Further, in the present invention, it is preferable that the control unit selects either the upper holding or the lower holding with respect to a mode of the hand to be inserted into the carrier or the temporary placement part according to gap information between the substrates placed in the carrier or the temporary placement part. As a result, the substrate processing apparatus can convey the substrate in the mode of the hand suitable for a gap between the substrates placed in the carrier or the temporary placement part.

Further, in the present invention, it is preferable that the control unit selects one of the upper holding and the lower holding with respect to a mode of the hand to be inserted into the carrier or the temporary placement part according to gap information formed at an uppermost portion in the carrier or the temporary placement part. As a result, the substrate processing apparatus can convey the substrate in the mode of the hand suitable for a gap formed at the uppermost portion in the carrier or the temporary placement part.

Further, in the present invention, it is preferable that the processing unit has at least two types of a first processing unit, a second processing unit, and a third processing unit, the first processing unit has the upper holding as a mode of the hand in which a substrate is loaded and unloaded, the second processing unit has the lower holding as a mode of the hand in which a substrate is loaded and unloaded, the third processing unit has both the upper holding and the lower holding as a mode of the hand in which a substrate is loaded and unloaded, and the control unit selects a mode of the hand according to a type of the processing unit. As a result, the substrate processing apparatus can convey the substrate in the mode of the hand suitable for the type of the processing unit.

Further, in the present invention, it is preferable that a mode of the hand when a substrate is loaded and unloaded is the upper holding or the lower holding, and the control unit changes a mode of the hand in which a substrate has been unloaded from the carrier or the temporary placement part according to a mode of the hand when the substrate is loaded into the processing unit. As a result, the substrate processing apparatus can convey the substrate in the mode of the hand suitable for the processing unit in a case where the mode of the hand in which the substrate has been unloaded from the carrier or the temporary placement part is different from the mode of the hand when the substrate is loaded into the processing unit.

Further, in the present invention, it is preferable that the control unit changes a mode of the hand in which a substrate has been unloaded from the carrier in accordance with a mode of the hand in which a substrate is loaded into the processing unit in a state where a substrate unloaded from the carrier is temporarily placed in the temporary placement part. As a result, in a case where the mode of the hand cannot be changed while holding the substrate, the substrate processing apparatus can convey the substrate in the mode of the hand suitable for the processing unit.

Further, in the present invention, it is preferable that the control unit changes the upper holding hand to the lower holding hand or changes the lower holding hand to the upper holding hand. As a result, the substrate processing apparatus can transfer the substrate with the hand suitable for the processing unit among the upper holding hand and the lower holding hand.

Further, in the present invention, it is preferable that the control unit changes a surface for holding a substrate from the upper surface to the lower surface, or changes a surface for holding a substrate from the lower surface to the upper surface. As a result, the substrate processing apparatus can transfer the substrate on a surface suitable for the processing unit among the upper surface or the lower surface of the hand.

Further, in the present invention, it is preferable that the control unit changes a mode of the hand in which the substrate has been unloaded from the carrier or the temporary placement part in a state where the hand holds the substrate according to a mode of the hand in which the substrate is loaded into the processing unit. As a result, the substrate processing apparatus can convey the substrate in the mode of the hand suitable for the processing unit while holding the substrate.

In the present invention, it is preferable that the control unit changes a mode of the hand by controlling a reverse portion that reverses one surface on which the guide is provided and an other surface on which the guide is not provided. As a result, the substrate processing apparatus can convey the substrate in the mode of the hand in which the substrate is reversed to a surface suitable for the processing unit.

Further, in the present invention, it is preferable that the control unit does not perform the change in a case where a mode of the hand in which a substrate has been unloaded from the carrier or the temporary placement part is a same as a mode of the hand in which the substrate is loaded into the processing unit. As a result, the substrate processing apparatus can convey the substrate to the processing unit in the mode of the hand in which the substrate has been unloaded from the carrier or the temporary placement part.

Further, in the present invention, it is preferable that the substrate transfer apparatus can transfer the substrate placed in the carrier to one of the processing unit and the temporary placement part. As a result, the substrate processing apparatus can transfer the substrate in the mode of the hand suitable for the processing unit in both the case of transferring the substrate from the carrier to the processing unit and the case of transferring the substrate from the carrier to the processing unit via the temporary placement part.

Further, in the present invention, it is preferable that the substrate transfer apparatus loads the substrate unloaded from the carrier into the temporary placement part. As a result, the substrate processing apparatus can transfer the substrate in the mode of the hand suitable for the processing unit in a case where the substrate is transferred from the carrier to the temporary placement part.

In the present invention, it is preferable that the substrate transfer apparatus transfers the substrate unloaded from the temporary placement part to the processing unit. As a result, the substrate processing apparatus can transfer the substrate in the mode of the hand suitable for the processing unit in a case where the substrate is transferred from the temporary placement part to the processing unit.

### BRIEF DESCRIPTION OF THE DRAWINGS

※ For the purpose of illustrating the invention, there
are shown in the drawings several forms which are
presently preferred, it being understood, however, that
the invention is not limited to the precise arrangement
and instrumentalities shown.

FIG. 1 is a plan view illustrating a schematic configuration of a substrate processing apparatus according to a first embodiment;

FIG. 2 is a view of the substrate processing apparatus of FIG. 1 as viewed from a front side X;

FIGS. 3A to 3E are side views illustrating a configuration and an operation of a loading/unloading block;

FIG. 4 is a side view illustrating a first example of a placement part included in a processing unit;

FIG. 5 is a side view illustrating a second example of the placement part included in the processing unit;

FIG. 6 is a side view illustrating a third example of the placement part included in the processing unit;

FIG. 7 is a plan view of a first hand (lower holding hand) according to the first embodiment;

FIG. 8 is a side view of the hand according to the first embodiment;

FIG. 9 is a longitudinal sectional view illustrating a configuration of the movable guide on a distal end side;

FIG. 10 is a longitudinal sectional view illustrating the configuration of the movable guide (pusher) on a proximal end side;

FIG. 11 is a side view of a second hand (upper holding hand) according to the embodiment;

FIG. 12 is a block diagram illustrating a control system;

FIG. 13 is a flowchart illustrating an operation related to transfer;

FIG. 14 is a schematic view for explaining the operation in side view;

FIG. 15 is a schematic view for explaining the operation in plan view;

FIG. 16 is a schematic view for explaining the operation in side view;

FIG. 17 is a schematic view for explaining the operation in plan view;

FIG. 18 is a schematic view for explaining the operation in side view;

FIG. 19 is a schematic view for explaining the operation in plan view;

FIG. 20 is a schematic view for explaining the operation in side view;

FIG. 21 is a schematic view for explaining the operation in plan view;

FIG. 22 is a schematic view for explaining the operation in side view;

FIG. 23 is a schematic view for explaining the operation in side view;

FIG. 24 is a view for explaining an operation related to transfer using the first hand and the second hand;

FIGS. 25A to 25D are views for explaining the operation according to a first transfer pattern in side view;

FIG. 26A to 26D are views for explaining the operation according to the first transfer pattern in side view;

FIG. 27A to 27D are views for explaining the operation according to the first transfer pattern in side view;

FIGS. 28A to 28D are views for explaining the operation according to the first transfer pattern in side view;

FIGS. 29A to 29D are views for explaining the operation according to a second transfer pattern in side view;

FIGS. 30A to 30D are views for explaining the operation according to the second transfer pattern in side view;

FIGS. 31A to 31D are views for explaining the operation according to the second transfer pattern in side view;

FIGS. 32A to 32D are views for explaining the operation according to the second transfer pattern in side view;

FIG. 33 is a side view of the hand according to a second embodiment;

FIG. 34 is a side view of a hand according to a third embodiment;

FIG. 35 is a plan view illustrating a schematic configuration of a substrate processing apparatus according to a fourth embodiment;

FIG. 36 is a block diagram illustrating a control system; and

FIG. 37 is a view for explaining an operation related to transfer using the first hand and the second hand.

### DESCRIPTION OF THE PREFERRED EMBODIMENTS

The present invention will be described below with reference to various embodiments.

### First Embodiment

Hereinafter, a first embodiment of the present invention will be described with reference to the drawings.

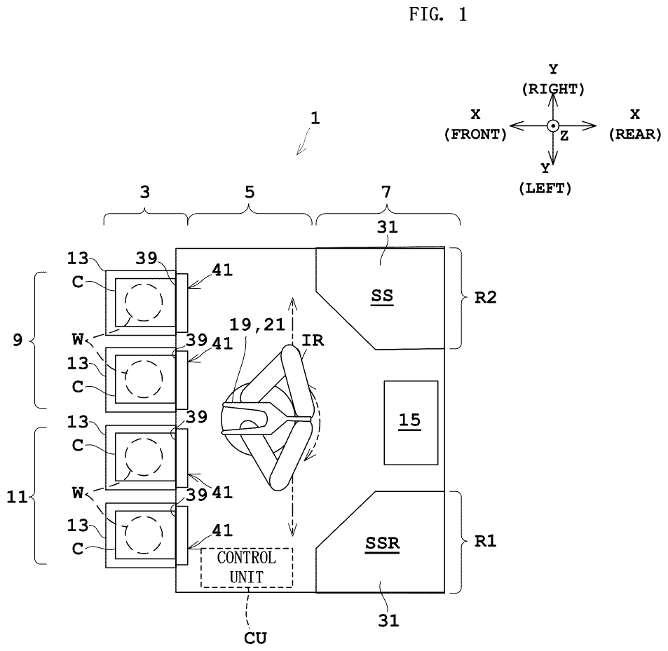

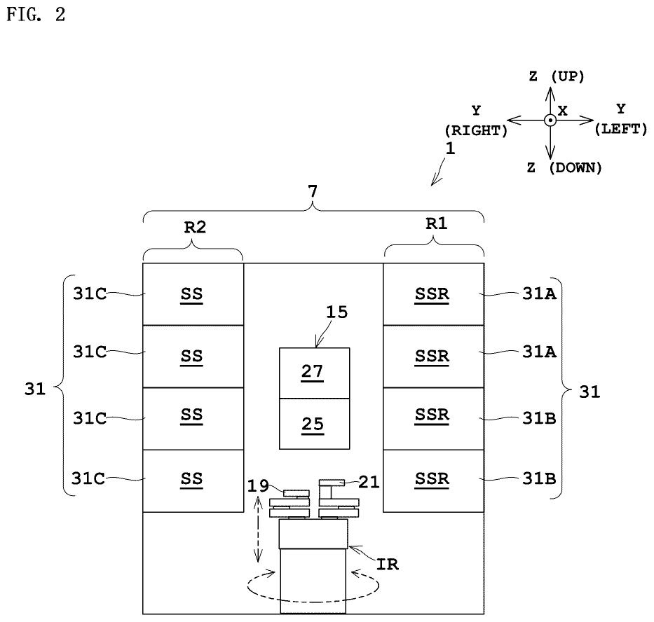

FIG. 1 is a plan view illustrating an overall configuration of a substrate processing apparatus according to the first embodiment. FIG. 2 is a view of the substrate processing apparatus of FIG. 1 as viewed from a rear side X.

### <1. Overall Configuration>

A substrate processing apparatus 1 includes a loading/unloading block 3, an indexer block 5, and a processing block 7.

The substrate processing apparatus 1 processes a substrate W. The substrate processing apparatus 1 performs, for example, cleaning processing on the substrate W. The substrate processing apparatus 1 processes the substrate W in a single wafer type in the processing block 7. In the single wafer type, one substrate W is processed one by one in a horizontal posture. The substrate W has, for example, a circular shape in plan view.

In the present specification, for convenience, a direction in which the loading/unloading block 3, the indexer block 5, and the processing block 7 are arranged is referred to as a “front-rear direction X”. The front-rear direction X is horizontal. In the front-rear direction X, the direction from the processing block 7 toward the loading/unloading block 3 is referred to as a “front side”. A direction opposite to the front side is referred to as a “rear side”. A horizontal direction orthogonal to the front-rear direction X is referred to as a “width direction Y”. One direction in the “width direction Y” is appropriately referred to as a “right side”. A direction opposite to the right side is referred to as a “left side”.

A direction perpendicular to the horizontal direction is referred to as a “vertical direction Z”. In each drawing, front, rear, right, left, up, and down are appropriately shown for reference.

### <2. Loading/Unloading Block>

The loading/unloading block 3 includes a feeding unit 9 and a dispensing unit 11. The feeding unit 9 and the dispensing unit 11 are disposed in the width direction Y.

A plurality of (for example, 25 sheets) substrates W are stacked and stored in one carrier C at constant intervals in a horizontal posture. The carrier C storing the untreated substrate W is placed in the feeding unit 9. The feeding unit 9 includes, for example, two placing tables 13 on which the carrier C is placed. In the carrier C, a plurality of grooves (not illustrated) for accommodating the substrates W one by one are formed with the surfaces of the substrates W separated from each other. The carrier C is accommodated, for example, in a posture in which the surface of the substrate W faces upward. As the carrier C, for example, there is a front opening unify pod (FOUP). The FOUP is a sealed container. The carrier C may be an open type container and may be of any type.

The dispensing unit 11 is disposed on the opposite side of the feeding unit 9 across the central portion in the width direction Y in the substrate processing apparatus 1. The dispensing unit 11 is disposed on the left side Y of the feeding unit 9. The dispensing unit 11 stores the processed substrate W in the carrier C and dispenses the processed substrate W together with the carrier C. Similarly to the feeding unit 9, the dispensing unit 11 functioning in this manner includes, for example, two placing tables 13 for placing the carrier C. The feeding unit 9 and the dispensing unit 11 are also called load ports.

### <3. Indexer Block>

The indexer block 5 is disposed adjacent to the rear side X of the loading/unloading block 3 in the substrate processing apparatus 1. The indexer block 5 includes an indexer robot IR.

The indexer robot IR is configured to be rotatable about the vertical direction Z. The indexer robot IR is configured to be movable in the width direction Y. The indexer robot IR includes a first hand 19 and a second hand 21. FIG. 1 illustrates only one hand for the sake of illustration. The first hand 19 and the second hand 21 hold the substrate W in a horizontal posture. The first hand 19 is a lower holding hand adopting a lower holding type described later. The first hand 19 clamps the outer peripheral surface of the substrate W and holds the substrate W separated from the upper surface of the first hand 19. The second hand 21 is an upper holding hand adopting an upper holding type described later. The second hand 21 clamps the outer peripheral surface of the substrate W and holds the substrate W separated from the lower surface of the second hand 21.

Each of the first hand 19 and the second hand 21 holds one substrate W. The first hand 19 and the second hand 21 are independently movable forward and backward in the front-rear direction X. The first hand 19 and the second hand 21 are configured to be independently movable up and down in the up-down direction Z. The indexer robot IR moves in the up-down direction Z and the width direction Y and rotates around the vertical direction Z, and advances or retracts the first hand 19 and the second hand 21 in the front-rear direction X to deliver the substrate W to and from each carrier C. The indexer robot IR delivers the substrate W to and from a delivery part 15 and a processing unit 31.

### <4. Processing Block>

The processing block 7 performs, for example, various types of processing on the substrate W. Examples of the processing include cleaning processing. The cleaning processing is, for example, treatment liquid cleaning processing performed by supplying only a cleaning liquid, or brush cleaning processing using a brush in addition to the treatment liquid.

As illustrated in FIG. 1, for example, the processing block 7 is divided into a first row R1 and a second row R2 in the width direction Y. Specifically, the first row R1 is disposed on the left side Y of a placement part 15. The second row R2 is disposed on the right side Y of the placement part 15.

### <4-1. First Row>

The first row R1 of the processing block 7 includes a plurality of processing units 31. The first row R1 includes, for example, four processing units 31. The first row R1 is arranged by stacking four processing units 31 in the vertical direction Z. Each processing unit 31 is, for example, a cleaning unit. The cleaning unit cleans the substrate W. Examples of the cleaning unit include a front surface cleaning unit for cleaning the front surface of the substrate W and a rear surface cleaning unit for cleaning the rear surface of the substrate W. In the present embodiment, a rear surface cleaning unit SSR will be described as an example of the processing unit 31 in the first row R1. In the processing units 31 of the first row R1, for example, two processing units 31A to be described later are disposed, and two processing units 31B to be described later are disposed.

### <4-2. Second Row>

The second row R2 of the processing block 7 includes a plurality of processing units 31. The second row R2 includes, for example, four processing units 31. The second row R2 is arranged by stacking four processing units 31 in the vertical direction Z. In the present embodiment, a front surface cleaning unit SS will be described as an example of the processing unit 31 of the second row R2. In the processing units 31 in the second row R2, for example, four processing units 31C to be described later are disposed.

### <4-3. Delivery Part>

The processing block 7 includes the delivery part 15 between the first row R1 and the second row R2. The delivery part 15 is formed to be long in the vertical direction Z. The delivery part 15 includes a path part 25 and a path part 27 from the lower side to the upper side in the vertical direction Z. The path parts 25 and 27 are used to deliver the substrates W between an indexer block 5 and the processing block 7. The path part 25 is used, for example, to transfer the substrate W from the processing block 7 to the indexer block 5. The path part 27 is used, for example, to transfer the substrate W from the indexer block 5 to the processing block 7. Note that the transfer directions of the substrates W in the path parts 25 and 27 may be opposite to each other.

### <5. Placing Table>

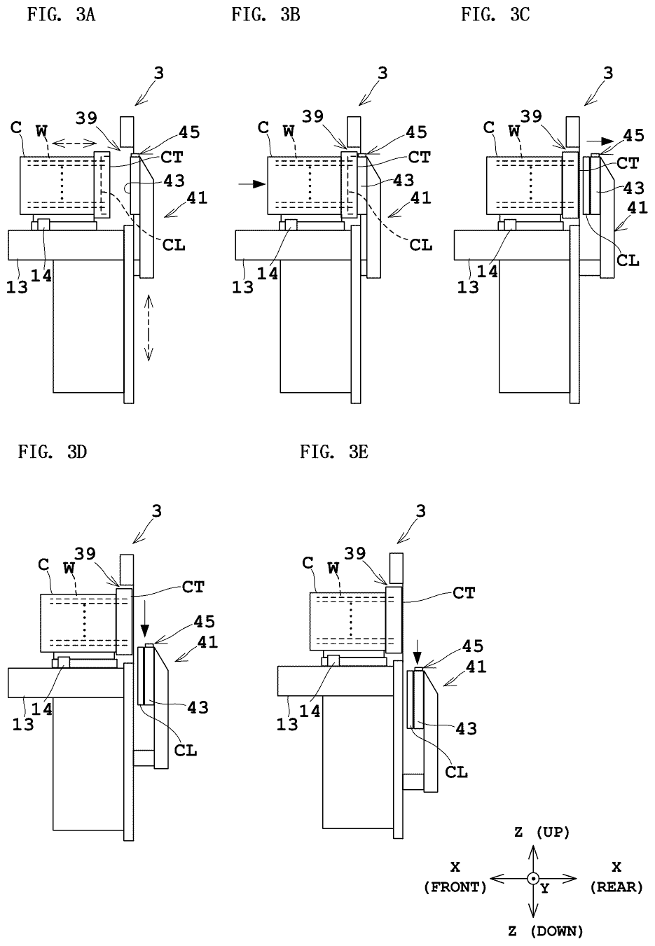

Here, the above-described loading/unloading block 3 will be described in detail with reference to FIGS. 1, and 3A to 3E. FIGS. 3A to 3E are side views illustrating a configuration and an operation of the loading/unloading block.

The loading/unloading block 3 includes a placing table 13, an opening 39, and a lid opening/closing mechanism 41. The carrier C is placed on the placing table 13. The placing table 13 includes a mechanism (not illustrated) that moves the carrier C in the front-rear direction X. The placing table 13 can advance or retract the carrier C with respect to the opening 39. The carrier C has a loading/unloading port CT. The loading/unloading port CT is formed on one side surface of the carrier C.

The plurality of substrates W stacked and accommodated in the carrier C are loaded and unloaded via the loading/unloading port CT. The carrier C includes a lid CL. The lid CL is configured to be detachable from the loading/unloading port CT of the carrier C. The lid CL seals the inside of the carrier C. When the lid CL is attached to the carrier C, the atmosphere from the outside of the carrier C is blocked.

The lid opening/closing mechanism 41 includes a detachable unit 43 on the front side X. The detachable unit 43 detaches the lid CL from the carrier C and attaches the lid CL to the carrier C. The detachable unit 43 is movable in the vertical direction Z and the front-rear direction X while holding the lid CL. The lid opening/closing mechanism 41 is movable in the front-rear direction X at the opening 39 in a state of holding the lid CL. The lid opening/closing mechanism 41 is movable up and down in the vertical direction Z in a state of holding the lid CL. The lid opening/closing mechanism 41 can move downward in the vertical direction Z from the opening 39 in a state of holding the lid CL. The lid opening/closing mechanism 41 can fully open the opening 39 by lowering in a state of holding the lid CL.

First, as illustrated in FIG. 3A, the carrier C is placed on the placing table 13. A plurality of substrates W are stacked and accommodated in the carrier C, and the carrier C is closed by the lid CL. At this time, the lid opening/closing mechanism 41 positions the detachable unit 43 in the opening 39. Accordingly, the inside of the indexer block 5 is separated from the external atmosphere.

As illustrated in FIG. 3B, the placing table 13 moves the carrier C to the rear side X. In the carrier C, the loading/unloading port CT and the lid CL are located in the opening 39. At this time, the detachable unit 43 unlocks the lid CL and holds the lid CL. The holding is performed, for example, by the detachable unit 43 sucking the lid CL.

As illustrated in FIG. 3C, the lid opening/closing mechanism 41 moves to the rear side X. Thus, the lid CL is moved from the opening 39 to the rear side X. The lid CL is moved to the inside of the indexer block 5.

As illustrated in FIG. 3D, the lid opening/closing mechanism 41 moves downward in the vertical direction Z. The lid opening/closing mechanism 41 lowers the detachable unit 43 to the lower part of the loading/unloading port CT. The lid opening/closing mechanism 41 is lowered until the upper portion of the detachable unit 43 is positioned at the lower portion of the opening 39.

As illustrated in FIG. 3E, the lid opening/closing mechanism 41 moves downward in the vertical direction Z, and moves to the lowermost portion where the lid opening/closing mechanism 41 can move. The lid opening/closing mechanism 41 is lowered to a position where the detachable unit 43 does not overlap the opening 39 in the front-rear direction X. As a result, the opening 39 is fully opened. The plurality of substrates W in the carrier C can face the indexer block 5 through the opening 39.

The lid opening/closing mechanism 41 described above includes, for example, a substrate sensor 45 in the detachable unit 43. The substrate sensor 45 is used to detect the position of the substrate W stacked and stored in the carrier C and collect shape information based on the outer edge of the substrate W. The shape information includes information regarding the thickness based on the outer edge of the substrate W.

Note that the indexer robot IR may include a photographing unit instead of the substrate sensor 45 or together with the substrate sensor 45. The photographing unit photographs the projection images of the substrate W and the carrier C. The captured projection image is transmitted to a control unit CU. From the projection image of the substrate W, shape information of the substrate W such as warpage and thickness of the substrate W is acquired. The gap information between the substrates W placed in the carrier C is acquired by joining a plurality of projection images of the substrates W. From the projection image including the carrier C and the substrate W, the gap information between the uppermost substrate W of the carrier C and the ceiling can be acquired.

The carrier C has a barcode (not illustrated). The barcode is an identifier for identifying the carrier C or identifying the substrate W in the carrier C. The barcode is attached to, for example, the outer surface of the carrier C. A barcode reader 14 that reads a barcode is provided on, for example, the placing table 13. The barcode and the barcode reader 14 are configured such that the barcode reader 14 can read the barcode in a state where the carrier C is placed on the placing table 13.

The barcode includes, for example, information regarding the carrier C and processing condition information of the substrate W placed in the carrier C. The information regarding the carrier C is, for example, shelf number information of the carrier C, interval information of each shelf, or information specifying the substrate W placed in each shelf. The processing condition information of the substrate W placed in the carrier C is, for example, information on which processing unit 31 the substrate W placed in which shelf of the carrier C is processed.

### <6. Placement Part>

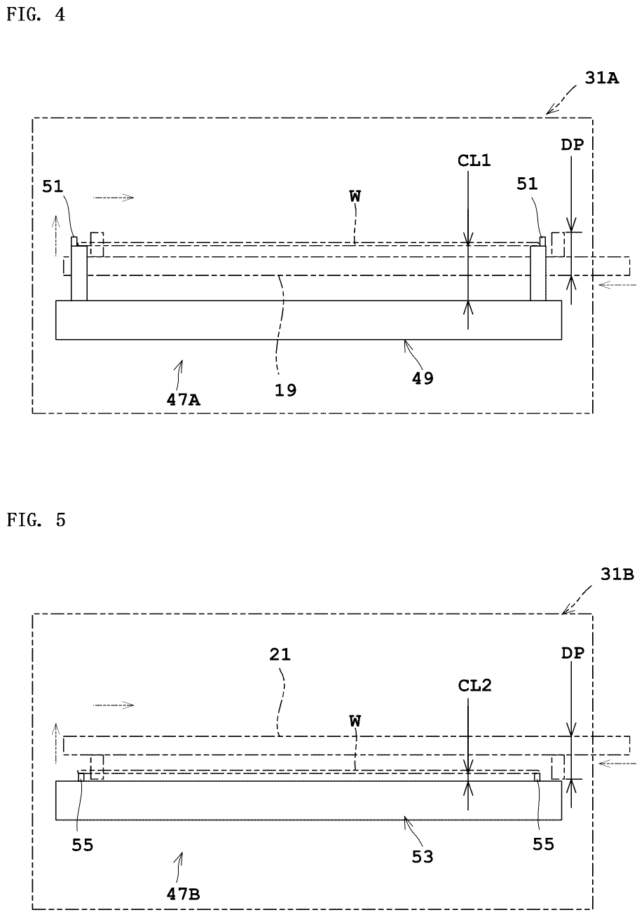

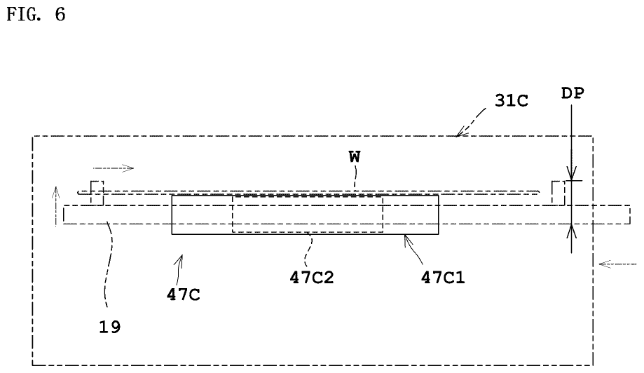

Here, a part of the processing unit 31 described above will be described with reference to FIGS. 4 to 6. FIG. 4 is a side view illustrating a first example of the placement part included in the processing unit. FIG. 5 is a side view illustrating a second example of the placement part included in the processing unit. FIG. 6 is a side view illustrating a third example of the placement part included in the processing unit.

The processing unit 31 described above is the front surface cleaning unit SS and the rear surface cleaning unit SSR. It is assumed that such a front surface cleaning unit SS and a rear surface cleaning unit SSR include, for example, any one of three types of placement parts 47 (placement parts 47A, 47B, 47C) as described below. The placement part 47 is a place where the substrate W is placed in the front surface cleaning unit SS and the rear surface cleaning unit SSR. The placement part 47 supports the lower surface of the substrate W.

As illustrated in FIG. 4, the placement part 47A includes a turning table 49 and a support pin 51. The turning table 49 has a circular shape in plan view. The turning table 49 has a diameter slightly larger than that of the substrate W. A plurality of support pins 51 are provided. The support pin 51 is erected on the upper surface of the turning table 49. The support pin 51 is disposed on an upper surface slightly inside the outer peripheral surface of the turning table 49. Some of the support pins 51 rotate eccentrically about the axis in the vertical direction Z. The substrate W is pressed in the horizontal direction from the outer peripheral surface by the support pins 51 rotating in this manner, and the position is fixed by the plurality of support pins 51. The support pins 51 abuts on the outer peripheral surface and the lower surface of the substrate W to support the lower surface of the substrate W to be separated from the upper surface of the turning table 49. The placement part 47A is a so-called mechanical chuck.

Here, the interval between the upper surface of the turning table 49 and the lower surface of the substrate W supported by the support pins 51 is referred to as a clearance CL1. The placement part 47A in the first example has a relatively large clearance CL1. The clearance CL1 is larger than a thickness DP of the first hand 19. The thickness DP corresponds to the maximum height in the vertical direction Z in a case where the portion of the first hand 19 entering the position to deliver the substrate W is viewed from the side.

In the cleaning unit SSR (hereinafter, referred to as a processing unit 31A) including such the placement part 47A, it is possible to access either the first hand 19 (lower holding hand) or the second hand 21 (upper holding hand).

As illustrated in FIG. 5, the placement part 47B includes a turning table 53 and a support projection 55. The turning table 53 has a circular shape in plan view. The turning table 53 includes an injection port (not illustrated) for supplying gas to the lower surface of the substrate W. The support projection 55 is formed on the upper surface of the turning table 53. The plurality of support projections 55 are provided. The support projection 55 is formed slightly inside the outer peripheral surface of the turning table 53. The support projections 55 abut on the lower surface of the substrate W to support the lower surface of the substrate W to be separated from the upper surface of the turning table 53. The substrate W is supported so as to be sucked by the support projections 55 and the turning table 53 by a negative pressure generated by supplying gas. As a result, the position of the substrate W is fixed. The placement part 47B is a so-called Bernoulli chuck.

A clearance CL2 of the placement part 47B is relatively small. The clearance CL2 is smaller than the clearance CL1. The clearance CL2 is smaller than the thickness DP of the second hand 21. The thickness DP corresponds to the maximum height in the vertical direction Z in a case where the portion of the second hand 21 entering the position to deliver the substrate W is viewed from the side.

In the cleaning unit SSR (hereinafter, referred to as a processing unit 31B) including such a placement part 47B, it is preferable to access with the second hand 21 (upper holding hand) described later.

As illustrated in FIG. 6, the placement part 47C includes a turning table 47C1 and a suction part 47C2 that performs vacuum suction at a central portion of the turning table 47C1. The diameter of the turning table 47C1 is smaller than the diameter of the substrate W. The suction part 47C2 holds the rear surface of the substrate W placed on the turning table 47C1 on the turning table 47C1 by vacuum suction. The rear surface of the substrate W is in contact with the upper surface of the turning table 47C1. The placement part 47C is a so-called suction chuck.

The placement part 47C has a device configuration in which the second hand 21 is hardly inserted on the upper side of the turning table 47C1. For example, in the placement part 47C, a clearance sufficiently larger than the thickness DP of the second hand 21 is not secured on the upper side of the turning table 47C1.

In the front surface cleaning unit SS (hereinafter, referred to as a processing unit 31C) including such a placement part 47C, it is preferable to access with the first hand 19 (lower holding hand) described later.

### <7. Details of Hand>

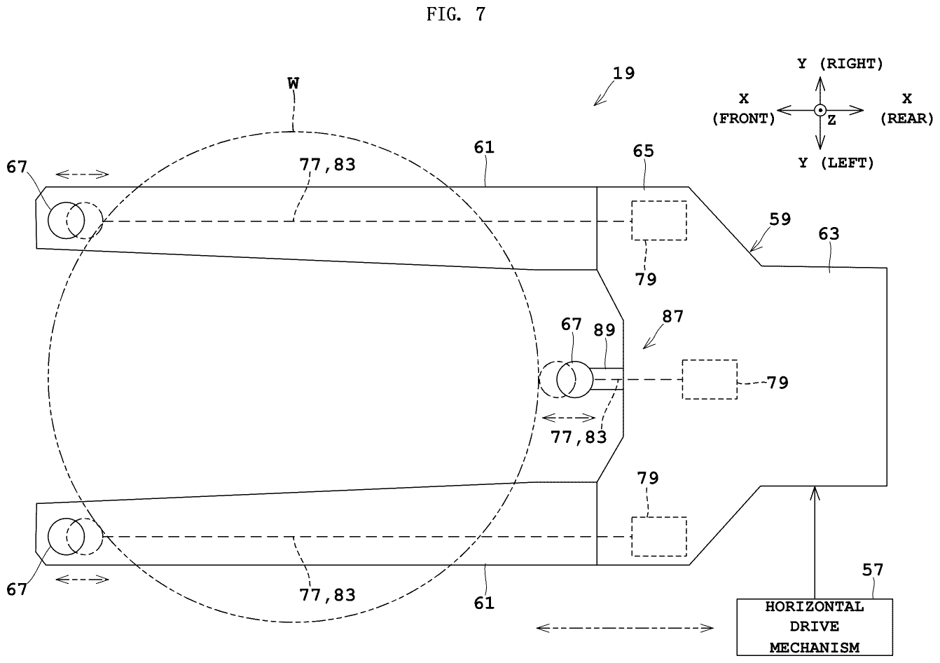

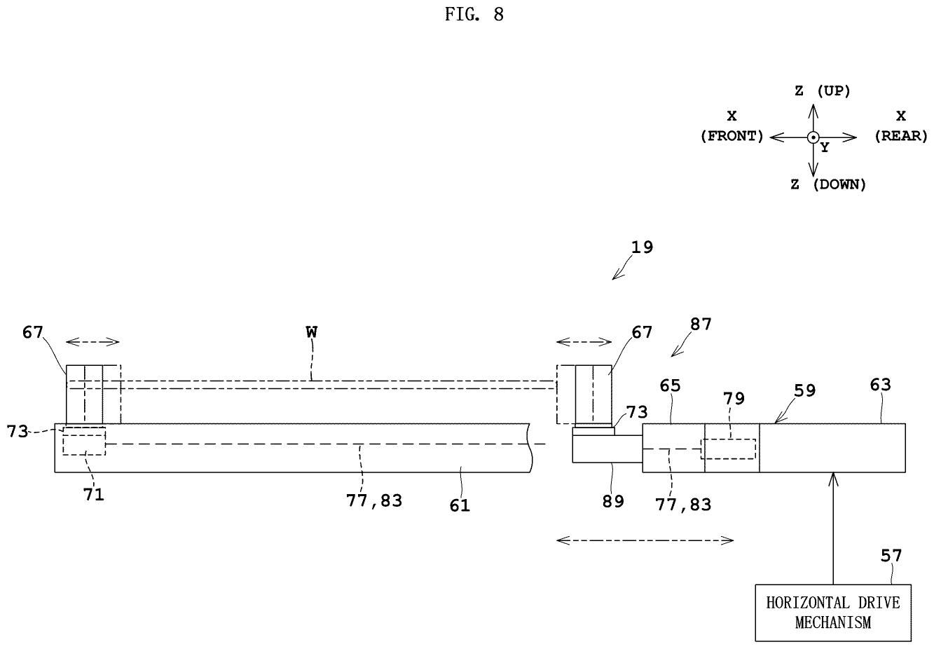

Here, the first hand 19 in the indexer robot IR will be described as an example with reference to FIGS. 7 to 11. The configuration of the first hand 19 is the same as that of the second hand 21.

The indexer robot IR includes a horizontal drive mechanism 57. The horizontal drive mechanism 57 drives the first hand 19 in the front-rear direction X. The horizontal drive mechanism 57 drives the first hand 19 to be advanced or retracted in the horizontal direction. The horizontal drive mechanism 57 drives the first hand 19 to be advanced or retracted with respect to the delivery destination. Specifically, the delivery destination in the indexer robot IR is driven to be advanced or retracted with respect to the carrier C, the delivery part 15, or the processing unit 31.

The first hand 19 includes one palm portion 59 and two finger portions 61. The palm portion 59 is a proximal end side of the first hand 19. The finger portion 61 is on the distal end side of the first hand 19. The delivery destination enters from the distal end side of the first hand 19 and exits from the proximal end side of the first hand 19. The palm portion 59 includes an attachment proximal end section 63 and a finger attachment section 65.

The attachment proximal end section 63 is attached to the horizontal drive mechanism 57. The finger portions 61 are attached to the finger attachment sections 65. The finger attachment sections 65 are provided at two positions spaced apart in the width direction Y. The portion of the finger attachment sections 65 to which the two finger portions 61 are attached are located outside the outer peripheral surface of the substrate W in plan view when the first hand 19 advances to the position to deliver the substrate W. In other words, the length of the finger portion 61 in the front-rear direction X is longer than the diameter of the substrate W.

The first hand 19 includes two finger portions 61. The two finger portions 61 extend in the front-rear direction X. The two finger portions 61 are separated from each other in the width direction Y. The distance by which the two finger portions 61 are separated from each other does not exceed the diameter of the substrate W. In other words, the width direction Y of the two finger portions 61 falls within the diameter of the substrate W. The proximal end side of the finger portion 61 is attached to the finger attachment section 65. The distal end side on the opposite side of the proximal end side of the finger portion 61 is in an open state. The first hand 19 has a U shape in plan view with the palm portion 59 and the two finger portions 61.

The first hand 19 includes three guides 67. Three guides 67 are attached to the upper surface of the first hand 19. The finger portion 61 includes one guide 67 on the distal end side. A structure in which the guide 67 is attached to the upper surface of the finger portion 61 like the first hand 19 is referred to as a “lower holding hand”. The first hand 19 having a structure of the lower holding hand holds the substrate W by scooping up the substrate W from below to above.

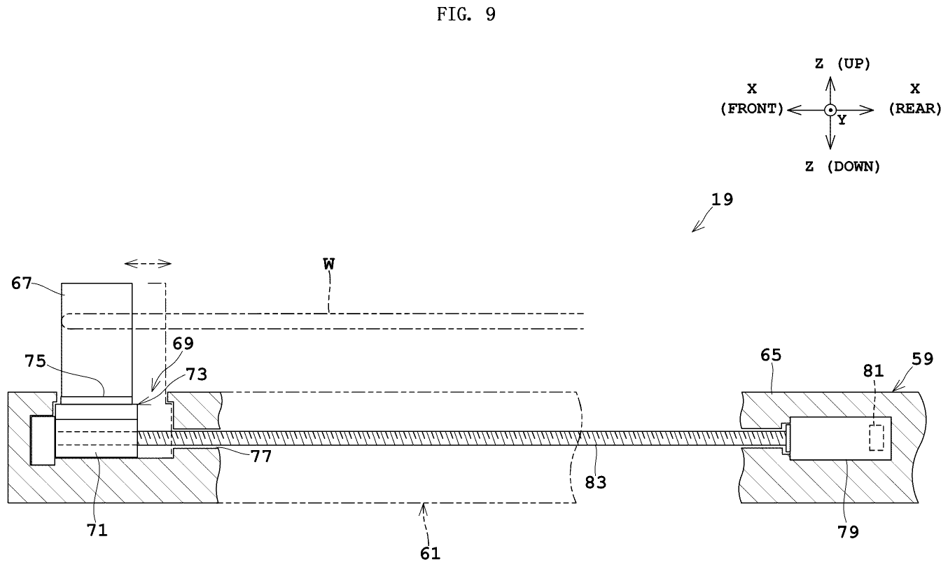

As illustrated in FIG. 9, the guide 67 of the finger portion 61 is attached to a guide hole 69. The guide hole 69 is long in the front-rear direction X. A movable piece 71 is disposed at the bottom of the guide hole 69. The movable piece 71 is movable only in the front-rear direction X at the bottom of the guide hole 69. A tactile sensor 73 is attached to the movable piece 71. The tactile sensor 73 is attached to the upper surface of the movable piece 71.

The tactile sensor 73 has a detection surface 75 capable of detecting force applied to each of three axes orthogonal to each other. The tactile sensor 73 is attached to the movable piece 71 in a posture in which the detection surface 75 is directed upward. The guide 67 is attached to the detection surface 75. The bottom of the guide 67 is attached to the detection surface 75. The tactile sensor 73 can detect the force applied to the guide 67 in each of the three axial directions. The tactile sensor 73 detects forces applied in the front-rear direction X, the width direction Y, and the vertical direction Z. The tactile sensor 73 outputs electrical signals corresponding to the respective forces detected in the three axial directions.

In the finger portion 61, a lateral hole 77 is formed in the front-rear direction X from the guide hole 69. The lateral hole 77 penetrates to the palm portion 59. In the palm portion 59, a servomotor 79 is provided at a position corresponding to an end portion of the lateral hole 77. The servomotor 79 includes an encoder 81. The encoder 81 detects a rotational position (rotation angle) of the rotation shaft of the servomotor 79, and outputs the rotational position as position information in the form of an electric signal. A ball screw 83 is inserted into the lateral hole 77. One end side of the ball screw 83 is connected to the rotation shaft of the servomotor 79. The movable piece 71 is screwed to the other end side of the ball screw 83. When the servomotor 79 is rotationally driven, the ball screw 83 is rotated, and the movable piece 71 moves in the front-rear direction X along the guide hole 69. As a result, the guide 67 moves in the front-rear direction X.

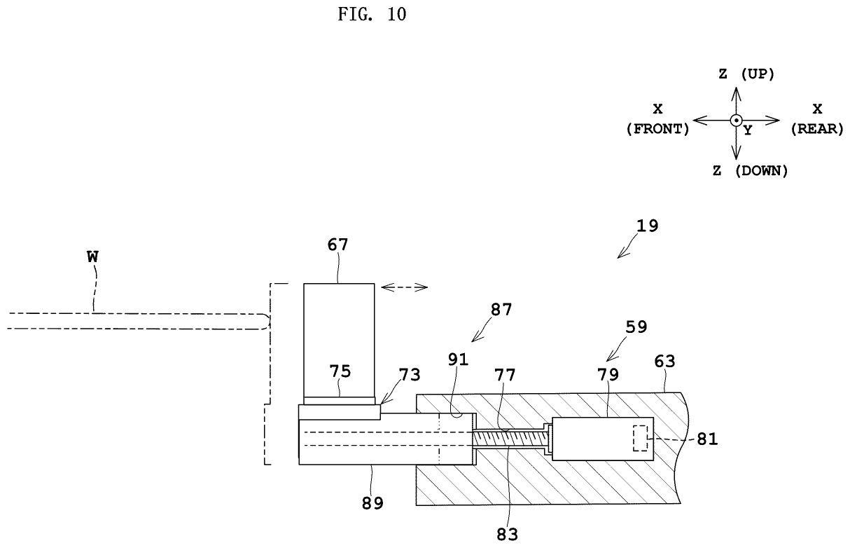

As illustrated in FIG. 10, the palm portion 59 includes a pusher 87. The pusher 87 includes one guide 67. The pusher 87 has the same configuration as the configuration for driving the guide 67 of the finger portion 61 except for a pusher arm 89 and a guide hole 91.

That is, the pusher 87 includes the tactile sensor 73, the lateral hole 77, the ball screw 83, the servomotor 79, the encoder 81, and the pusher arm 89. One end side of the lateral hole 77 penetrates a side surface on the finger portion 61 side. The guide hole 91 is formed on the finger portion 61 side of the lateral hole 77. The guide hole 91 has a larger dimension in the vertical direction Z than the lateral hole 77. A part of the pusher arm 89 is inserted into the guide hole 91 so as to be movable in the front-rear direction X. The other end side of the lateral hole 77 is closed inside the palm portion 59. The servomotor 79 is disposed on the other end side of the lateral hole 77. The servomotor 79 includes the encoder 81. One end side of the ball screw 83 is connected to the rotation shaft of the servomotor 79. The pusher arm 89 is screwed to the other end side of the ball screw 83. The pusher arm 89 includes the tactile sensor 73 on the opposite side of the servomotor 79 in the front-rear direction X. The guide 67 is attached to the detection surface 75 of the tactile sensor 73.

Each guide 67 described above is configured to be movable by a predetermined distance in the front-rear direction X. Each guide 67 described above is movable, for example, by a distance of about 5 mm in the front-rear direction X.

The first hand 19 includes three guides 67 on the upper surface. The first hand 19 holds the substrate W in a state where the lower surface of the substrate W is separated upward from the upper surface of the finger portion 61. Specifically, the outer peripheral surface of the substrate W is clamped by the three guides 67, and the lower surface of the substrate W is held in a state of floating from the upper surface of the finger portion 61. The first hand 19 holds the substrate W in a state of abutting on only the outer peripheral surface of the substrate W. The first hand 19 moves the three guides 67 toward the outer peripheral surface of the substrate W to clamp the outer peripheral surface of the substrate W with the three guides 67, and holds the substrate W in a state of being separated from the upper surface of the finger portion 61.

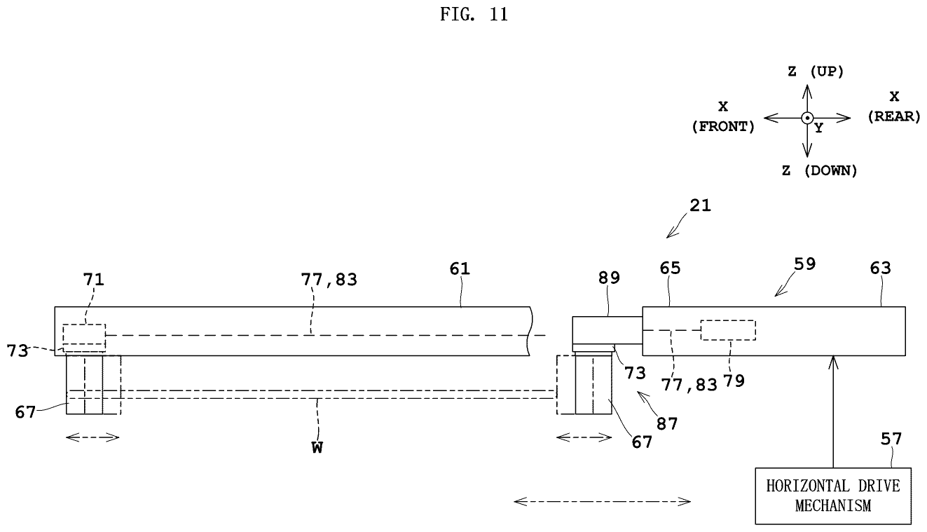

Although the first hand 19 includes the three guides 67 on the upper surface, the second hand 21 is configured as illustrated in FIG. 11. FIG. 11 is a side view of the upper holding hand according to the embodiment.

Unlike the first hand 19, three guides 67 are attached to the lower surface in the second hand 21. Specifically, each of the two finger portions 61 has one guide 67 on the distal end side on the lower surface. The palm portion 59 includes one guide 67 on the lower surface on the distal end side. The second hand 21 is referred to as an “upper holding hand”. The second hand 21, which is a structure of an upper holding hand, holds the substrate W so as to lift the substrate W upward from above.

The second hand 21 drives the three guides 67 with the same configuration except that the attachment surface of the guide 67 is different from that of the first hand 19 described above. Therefore, a detailed description of the drive mechanism will be omitted.

Each guide 67 described above is preferably made of, for example, PBI (polybenzimidazole). This is because PBI has high heat resistance, excellent chemical resistance, and robustness. However, each guide 67 may be made of another material. Examples of other materials include fluororesins such as PTFE (polytetrafluoroethylene) and PFA (perfluoroalkoxy alkane).

### <8. Control System>

A control system of the substrate processing apparatus 1 described above will be described with reference to FIG. 12. FIG. 12 is a block diagram illustrating the control system.

The substrate processing apparatus 1 is integrally controlled by the control unit CU. The control unit CU includes a CPU, a memory, and the like. The control unit CU transfers the substrate W to the processing unit 31 on the basis of a recipe defining a processing procedure, conditions, and the like of the substrate W to perform processing.

A shape information storage unit 93 stores the shape information for each substrate W obtained by the substrate sensor 45 in association with the substrate W. The shape information includes the thickness of the substrate W. The shape information includes warpage of the substrate W. The shape information storage unit 93 stores the warpage information and the thickness information of the substrate W in association with the mode information (hereinafter, referred to as loading/unloading mode information) of the hand in the carrier C. The loading/unloading mode information in the carrier C is information indicating which one of the first hand 19 (lower holding hand) and the second hand 21 (upper holding hand) is used for the substrate W. In the shape information storage unit 93, the shape information is referred to by the control unit CU.

A processing condition information storage unit 94 stores the processing condition information for each substrate W obtained by the barcode reader 14 in association with the substrate W. The processing condition information includes name information of the processing unit 31 that processes the substrate W. In the processing condition information storage unit 94, the processing condition information is referred to by the control unit CU.

The name information of the processing unit 31 is information for specifying the processing unit 31A including the above-described mechanical chuck (placement part 47A), the processing unit 31B including the Bernoulli chuck (placement part 47B), and the processing unit 31C including the suction chuck (placement part 47C). The processing condition information storage unit 94 stores the name information of the processing unit 31 in association with the loading/unloading mode information in the processing unit 31. The loading/unloading mode information in the processing unit 31 is information indicating whether the first hand 19 (lower holding hand), the second hand 21 (upper holding hand), or both the first hand 19 and the second hand 21 can be used as a hand when the substrate W is loaded into or unloaded from the processing unit 31.

Clamping information storage unit 95 stores the center position of the substrate W according to the position of the guide 67 when the substrate W is held by the first hand 19. The center position of the substrate W is acquired by the control unit CU via a clamping control unit 97 to be described later and written in the clamping information storage unit 95 by the control unit CU.

The clamping information storage unit 95 also stores clamping information in advance according to the shape of the substrate W. The clamping information is associated with each piece of shape information of the substrate W. The clamping information is a biasing force applied to the guide 67. The clamping information is information related to the biasing force applied to the guide 67 by the servomotor 79. The biasing force applied from the guide 67 to the substrate W and the torque applied from the servomotor 79 to the ball screw 83 are smaller as the substrate W is thinner, for example. These biasing forces and torques are smaller, for example, as the substrate W warps. These biasing forces and torques are larger, for example, as the substrate W is not warped and is thicker.

The clamping information is a biasing force or torque in a case where the substrate W having various shapes is actually held by the first hand 19 in advance, the substrate W and the guide 67 are not damaged at that time, and the substrate W can be held so as not to fall. The clamping information may be stored in advance in a separate device (not illustrated) and downloaded from a host computer (not illustrated) via a network.

The processing unit 31 includes the front surface cleaning unit SS, the rear surface cleaning unit SSR, and the like. The processing unit 31 includes the placement part 47A, the placement part 47B, and the placement part 47C described above. Processing of the processing unit 31 is controlled by the control unit CU. The control unit CU stores in advance that the processing unit 31A includes the placement part 47A, the processing unit 31B includes the placement part 47B, and the processing unit 31C includes the placement part 47C.

The indexer robot IR is controlled by the control unit CU. Movement of the indexer robot IR in the front-rear direction X, the width direction Y, and the vertical direction Z is operated by the control unit CU. Movement of the first hand 19 and the second hand 21 in the front-rear direction X is operated by the control unit CU via the horizontal drive mechanism 57.

The clamping control unit 97 independently operates the movement of each of the three guides 67. The clamping control unit 97 is operated by the control unit CU. The clamping control unit 97 operates each servomotor 79 on the basis of an instruction from the control unit CU to independently move the three guides 67. At that time, the clamping control unit 97 operates the servomotor 79 according to the position information from the encoder 81. The clamping control unit 97 operates a drive current to the servomotor 79. The clamping control unit 97 can detect the drive current supplied to the servomotor 79.

In a case where the tactile sensor 73 detects that the guide 67 abuts on the outer peripheral surface of the substrate W, the 97 clamping control unit 97 adjusts the biasing force of the guide 67 to the outer peripheral surface of the substrate W according to the shape information from the shape information storage unit 93, and clamps the substrate W. At this time, the guide 67 does not necessarily move from the outer peripheral surface side to the center side of the substrate W. That is, the guide 67 may not move in the center direction of the substrate W only by increasing the torque of the servomotor 79 to strengthen the biasing force to the outer peripheral surface of the substrate W.

In a case where the first hand 19 holds the substrate W by clamping the substrate W by the three guides 67, the control unit CU calculates the center position of the substrate W on the basis of the movement distance of the guide 67 at that time and stores the center position in the clamping information storage unit 95. The center position, which is stored in the clamping information storage unit 95, of the substrate W when the substrate W is clamped is generally shifted from the center position of the designed substrate W in the first hand 19. The clamping information that is the center position of the substrate W stored in the clamping information storage unit 95 is referred to by the control unit CU, and the control unit CU operates the indexer robot IR so as to correct the center position when placing the substrate W on the delivery part 15, and delivers the substrate W to the delivery part 15.

### <9. Operation Flow>

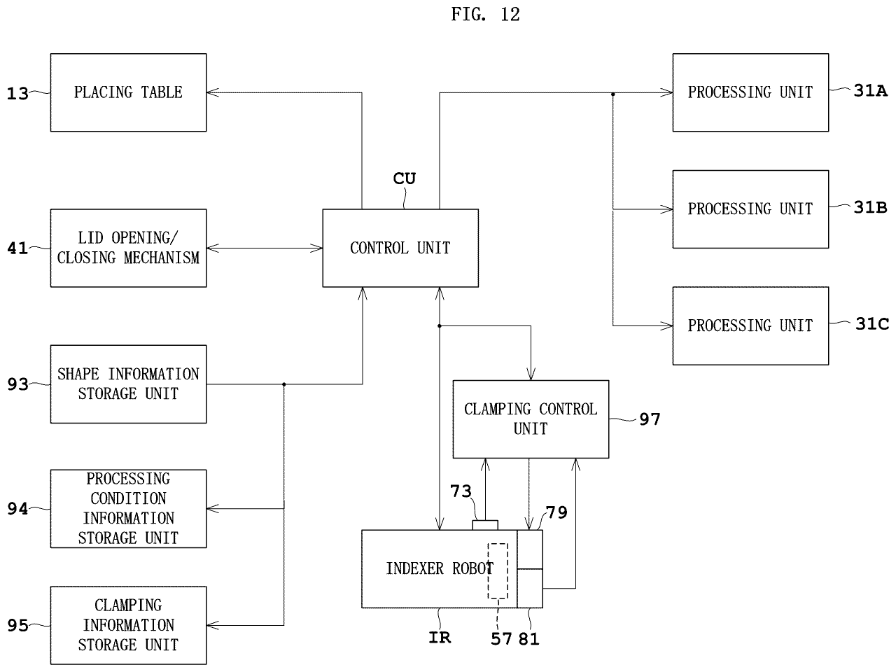

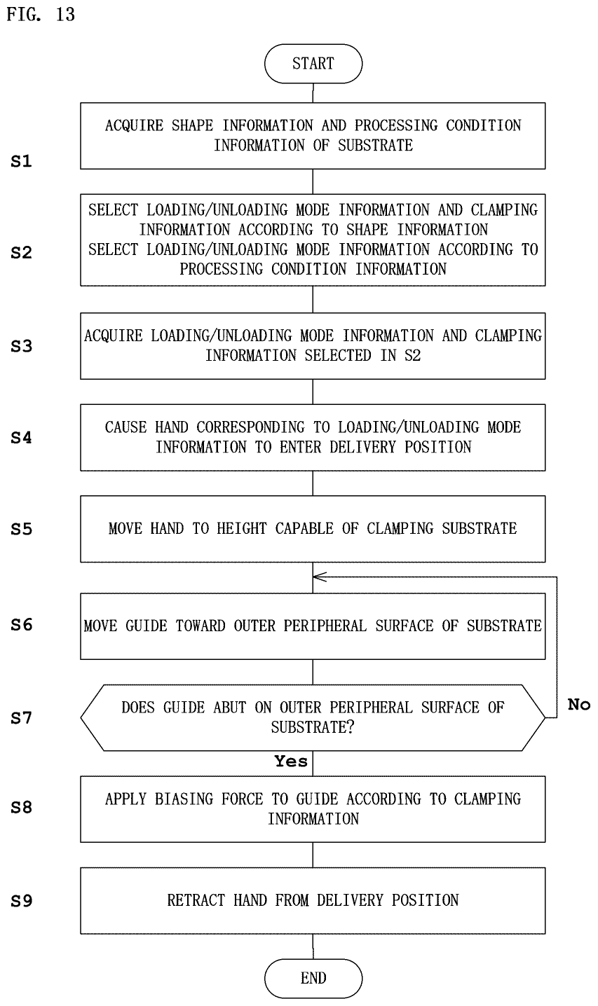

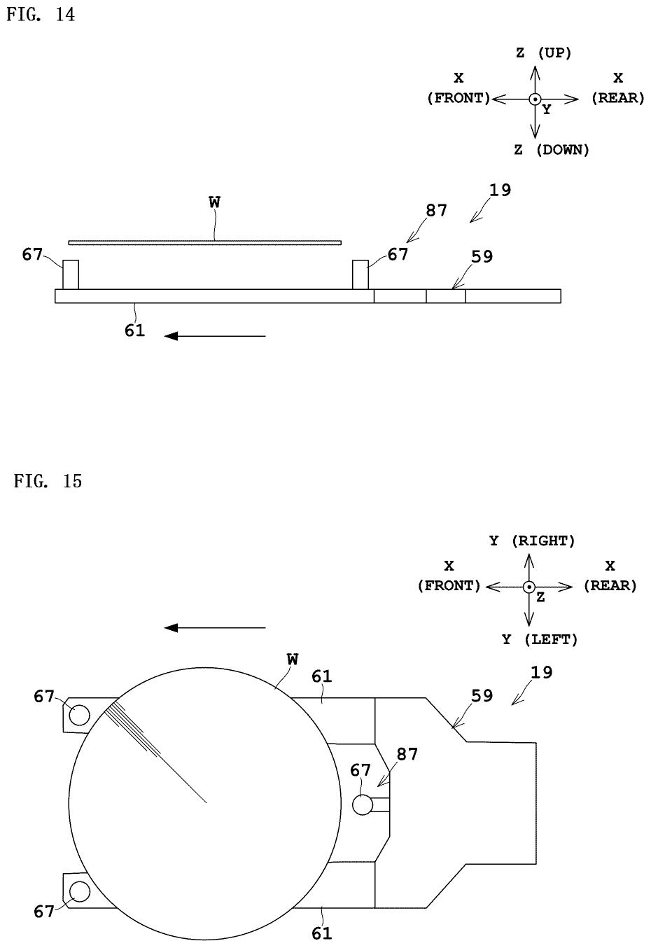

A transfer operation of the substrate W by the indexer robot IR in the substrate processing apparatus 1 will be described with reference to FIGS. 13 to 23. FIG. 13 is a flowchart for explaining an operation related to transfer. FIGS. 14, 16, 18, 20, 22, and 23 are schematic views for explaining the operation in side view. FIGS. 15, 17, 19, and 21 are schematic views for explaining the operation in plan view.

In the following description, an operation of unloading the substrate W from the carrier C will be described as an example. Note that this operation flow is applied to any of an operation of loading the substrate W into the carrier C, an operation of loading and unloading the substrate W into and from the delivery part 15, and an operation of loading and unloading the substrate W into and from the processing unit 31.

### Step S1

Shape information of the substrate W and processing condition information of the substrate W are acquired. When the carrier C is placed on the placing table 13, the control unit CU acquires the processing condition information of the substrate W by the barcode reader 14 reading the barcode attached to the carrier C. When the lid CL is detached from the carrier C by the detachable unit 43, the shape information of each substrate W is acquired by the substrate sensor 45. The control unit CU stores the acquired shape information in the shape information storage unit 93 in association with each substrate W. The control unit CU stores the acquired processing condition information in the processing condition information storage unit 94 in association with each substrate W. The acquired shape information of the substrate W and the processing condition information of the substrate W are stored in the shape information storage unit 93 until the processing of the substrate W in the substrate processing apparatus 1 is completed.

The acquisition of the shape information of the substrate W and the processing condition information of the substrate W includes reading the shape information of the substrate W and the processing condition information of the substrate W stored in the shape information storage unit 93 in the operation after the substrate W is unloaded from the carrier C, that is, the operation of loading and unloading the substrate W into and from the delivery part 15, the operation of loading and unloading the substrate W into and from the processing unit 31, and the operation of loading the substrate W into the carrier C.

The shape information of the substrate W is information regarding warpage and thickness of the substrate W.

The processing condition information of the substrate W is, for example, information for specifying the substrate W placed in the carrier C and information for specifying a processing recipe of the substrate W. The information for specifying the substrate W placed in the carrier C is, for example, information for specifying a shelf of the carrier C on which the substrate W is placed. The information for specifying the processing recipe of the substrate W is, for example, information for specifying the type of the processing unit 31 in which the substrate W is processed, information for specifying the order of processing, and information for specifying the contents of processing.

In a case where the indexer robot IR includes a photographing unit instead of the substrate sensor 45 or together with the substrate sensor 45, the control unit CU acquires gap information between the substrates W placed in the carrier C and gap information between the uppermost substrate W of the carrier C and the ceiling in addition to the shape information of the substrates W from the projection images of the substrates W and the carrier C captured by the photographing unit.

### Step S2

The control unit CU selects the loading/unloading mode information and the clamping information of the substrate W according to the shape information of the substrate W. The control unit CU selects the loading/unloading mode information of the substrate W according to the processing condition information of the substrate W. Specifically, for example, the control unit CU selects the loading/unloading mode information and the clamping information corresponding to the shape information of the substrate W transferred by the indexer robot IR from patterns of the loading/unloading mode information and the clamping information corresponding to the shape information of the substrate W stored in advance in the shape information storage unit 93.

In a case where the control unit CU acquires the gap information between the substrates W, the control unit CU selects the loading/unloading mode information of the substrates W according to the gap information between the substrates W. In a case where the control unit CU acquires the gap information between the uppermost substrate W of the carrier C and the ceiling, the control unit CU selects the loading/unloading mode information of the substrate W according to the gap information. Specifically, for example, the control unit CU selects the loading/unloading mode information of the substrates W corresponding to the gap information between the substrates W transferred by the indexer robot IR from the pattern of the loading/unloading mode information of the substrates W corresponding to the gap information between the substrates W stored in advance in the storage unit. The control unit CU selects the loading/unloading mode information of the substrate W corresponding to the gap information transferred by the indexer robot IR from among patterns of the loading/unloading mode information of the substrate W corresponding to the gap information between the uppermost substrate W of the carrier C and the ceiling stored in advance in the storage unit.

### Step S3

The control unit CU acquires the loading/unloading mode information and the clamping information selected in step S2. Specifically, for example, the control unit CU reads the loading/unloading mode information regarding the carrier C corresponding to the shape information of the substrate W selected in step S2 from the shape information storage unit 93. The control unit CU reads the clamping information corresponding to the shape information of the substrate W received by the first hand 19 selected in step S2 from the clamping information storage unit 95. The control unit CU reads the loading/unloading mode information regarding the carrier C corresponding to the processing condition information of the substrate W selected in step S2 from the shape information storage unit 93.

### Step S4

As illustrated in FIGS. 14 and 15, the control unit CU operates the horizontal drive mechanism 57 of the indexer robot IR to cause the hand corresponding to the loading/unloading mode information in the first hand 19 or the second hand 21 to enter the delivery position in the carrier C.

Here, it is assumed that the control unit CU selects the first hand 19 as the loading/unloading mode information in step S2 according to at least one of the shape information of the substrate W, the gap information between the substrates W, and the gap information between the uppermost substrate W of the carrier C and the ceiling acquired in step S1. Specifically, for example, it is assumed that the control unit CU determines that the substrate W is not warped on the basis of the shape information of the substrate W, determines that a sufficient gap for inserting the hand below the substrate W is secured on the basis of the gap information between the substrates W, and selects the first hand 19. In addition, when the control unit CU determines that both the first hand 19 and the second hand 21 can be inserted on the basis of the shape information of the substrate W and the gap information between the substrates W, the control unit CU may select the first hand 19 according to the loading/unloading mode information of the processing unit 31 on the basis of the processing condition information of the substrate W.

The first hand 19 enters the carrier C. Since the first hand 19 is a lower holding hand that receives the substrate W so as to lift the substrate W from below, the first hand 19 enters below the position where the substrate W to be received is placed. At this time, the control unit CU preferably expands the three guides 67 of the first hand 19 to the maximum. In other words, the guide 67 of the finger portion 61 is moved to the front side X to the maximum, and the guide 67 of the pusher 87 is moved to the rear side X to the maximum. As a result, even if the placement position of the substrate W is greatly shifted, the substrate W can be reliably received by the first hand 19.

### Step S5

As illustrated in FIGS. 16 and 17, the control unit CU moves the substrate W to a height at which the substrate W can be clamped by the first hand 19. Specifically, the control unit CU operates the indexer robot IR to raise the first hand 19 in the vertical direction Z so that the substrate W is positioned below the upper end of the guide 67 and above the upper surface of the finger portion 61.

### Step S6

As illustrated in FIGS. 18 and 19, the control unit CU operates the clamping control unit 97 to move the three guides 67 of the first hand 19 toward the outer peripheral surface of the substrate W.

### Step S7

The control unit CU branches the processing depending on whether each guide 67 abuts on the outer peripheral surface of the substrate W. Step S6 is repeated until each guide 67 abuts on the outer peripheral surface of the substrate W. In other words, the movement of each guide 67 toward the outer peripheral surface of the substrate W is maintained until each guide 67 abuts on the outer peripheral surface of the substrate W. Whether the substrate W abuts on the outer peripheral surface of the substrate W is determined by a signal of the tactile sensor 73.

### Step S8

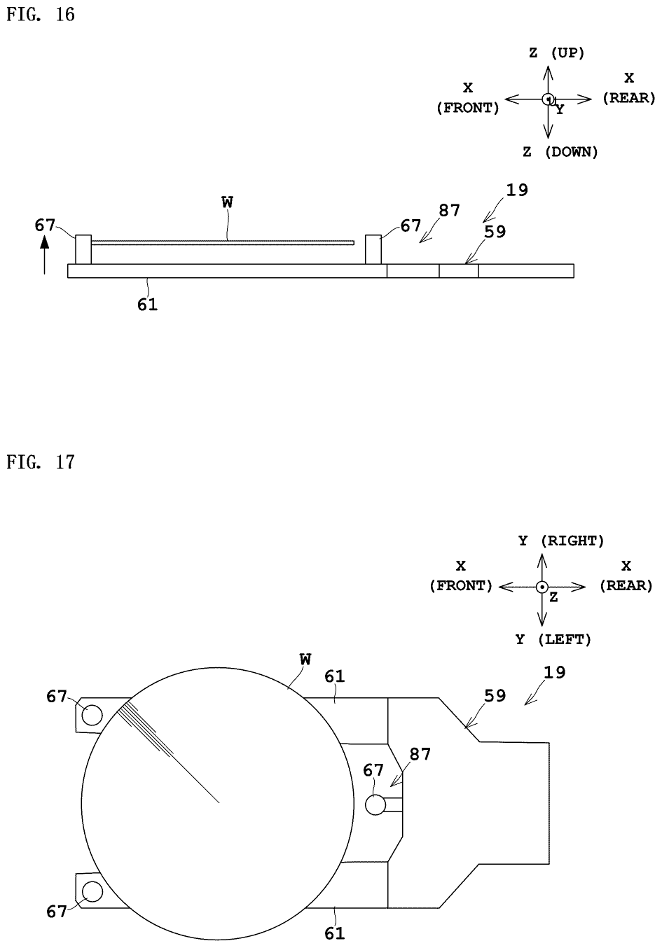

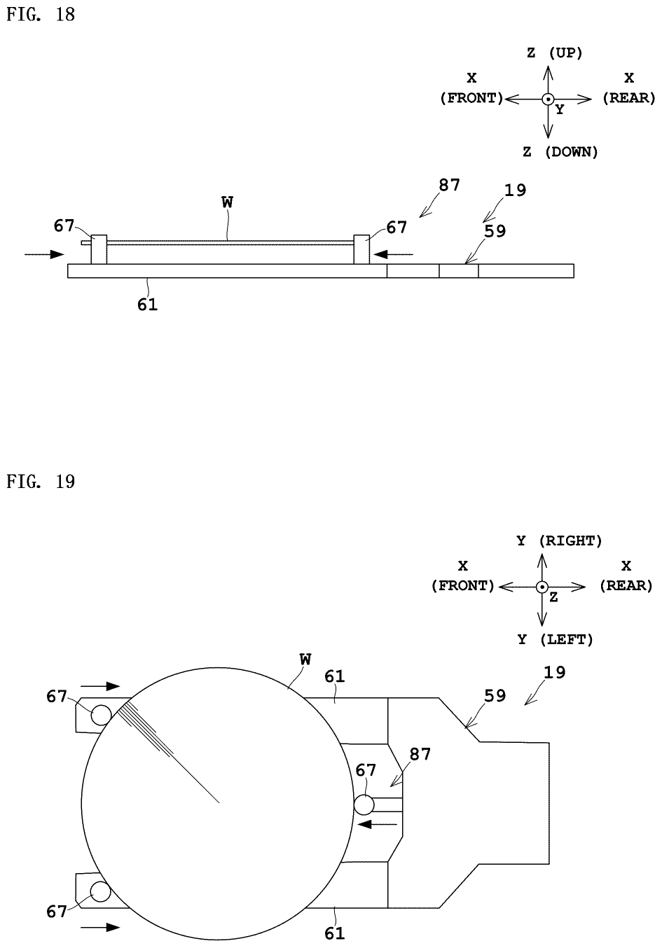

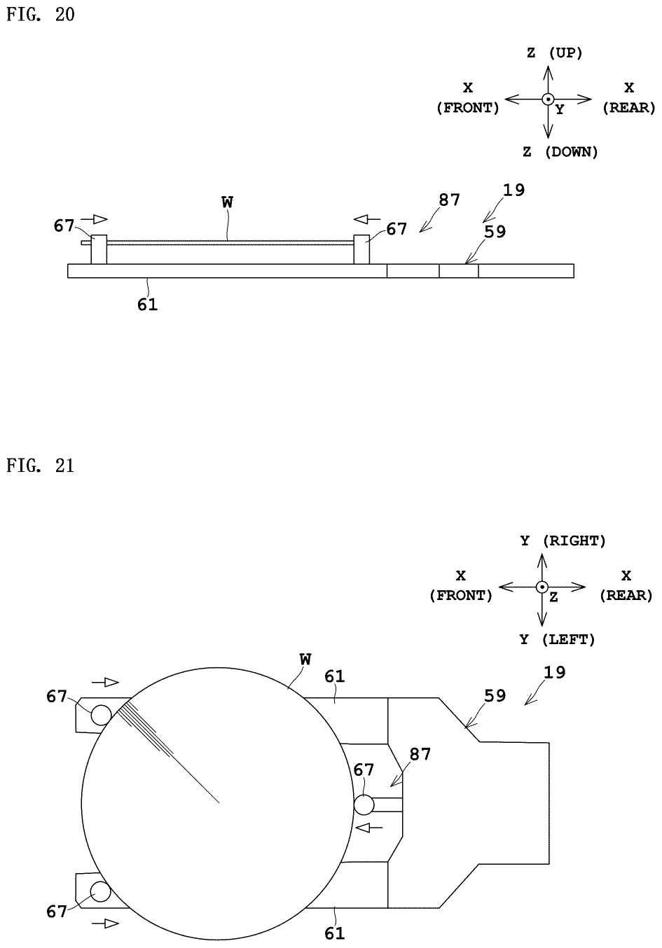

In a case where each guide 67 abuts on the outer peripheral surface of the substrate W, the following operation is performed. As illustrated in FIGS. 20 and 21, the control unit CU applies a biasing force (indicated by a white arrow in the drawing) to the guide 67 according to the clamping information.

Specifically, the control unit CU refers to the clamping information storage unit 95 and reads clamping information corresponding to the substrate W. The control unit CU operates the clamping control unit 97 according to the read clamping information to bias the guide 67. As a result, the guide 67 is pressed against the outer peripheral surface of the substrate W. Since each guide 67 is biased on the basis of the clamping information, the substrate W can be supported by each guide 67 so that the substrate W does not fall on the finger portion 61. In addition, since each guide 67 is biased on the basis of the clamping information, it is possible to suppress the occurrence of damage in the substrate W and the guide 67.

### Step S9

As illustrated in FIG. 22, the control unit CU operates the indexer robot IR to move the first hand 19 in the vertical direction Z by a predetermined distance. Next, as illustrated in FIG. 23, the control unit CU operates the horizontal drive mechanism 57 of the indexer robot IR to retract the first hand 19 out of the delivery position of the carrier C. Note that the above-described biasing force (indicated by a white arrow in the drawing) is maintained until the substrate W is transferred to the transfer destination.

### <10. Transfer Pattern>

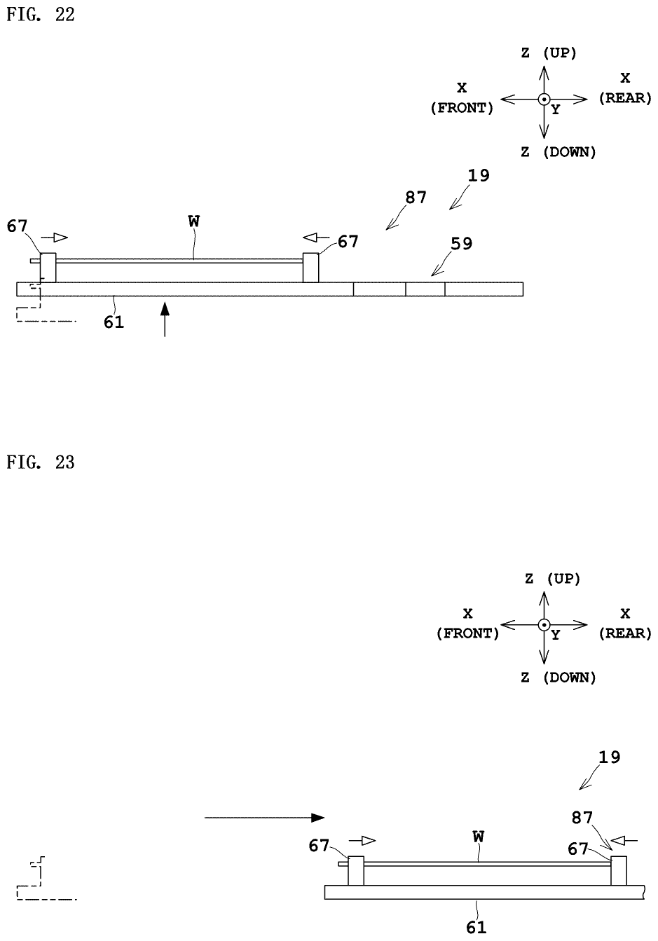

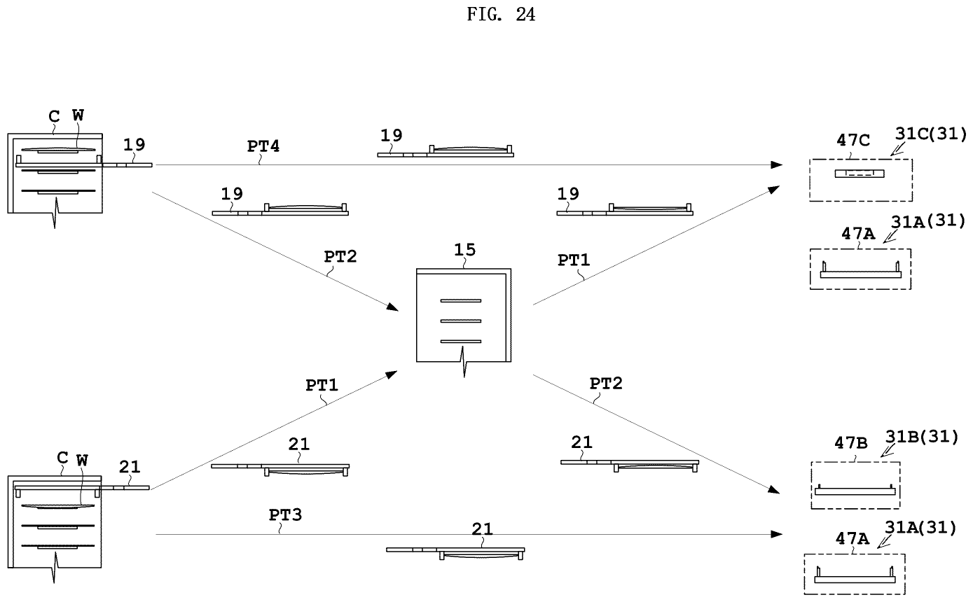

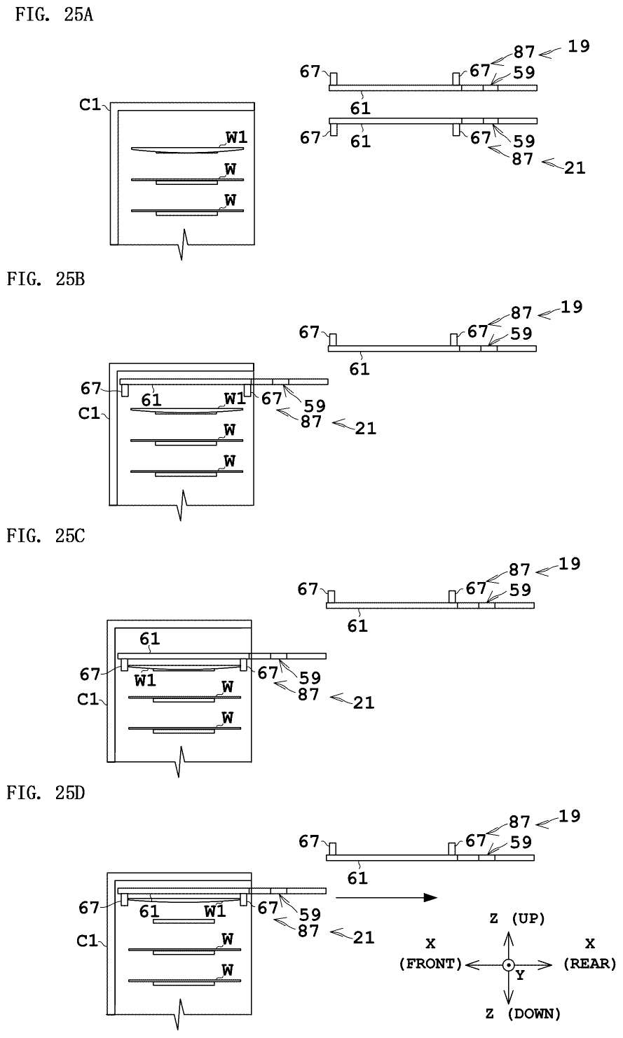

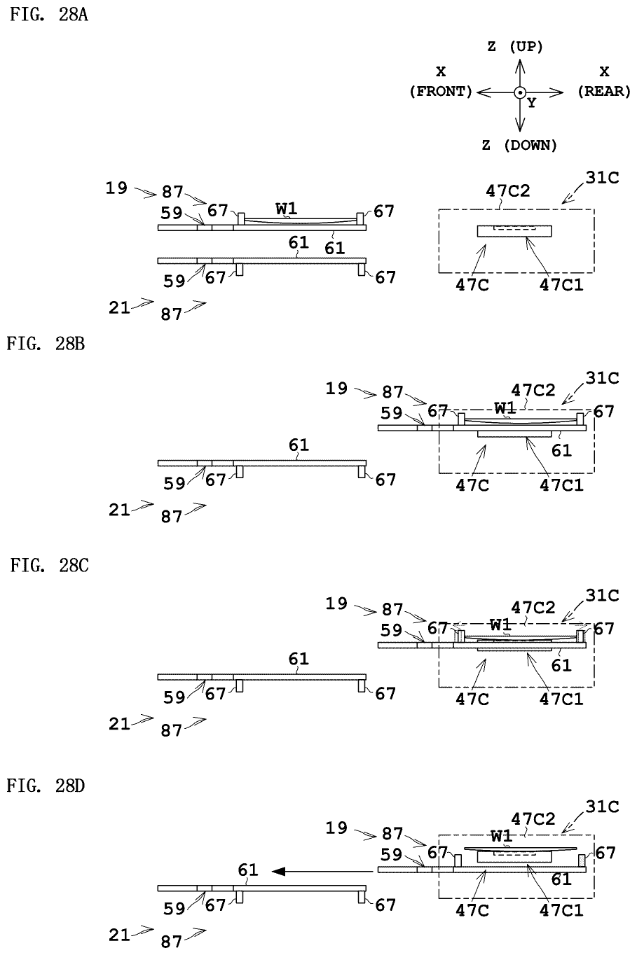

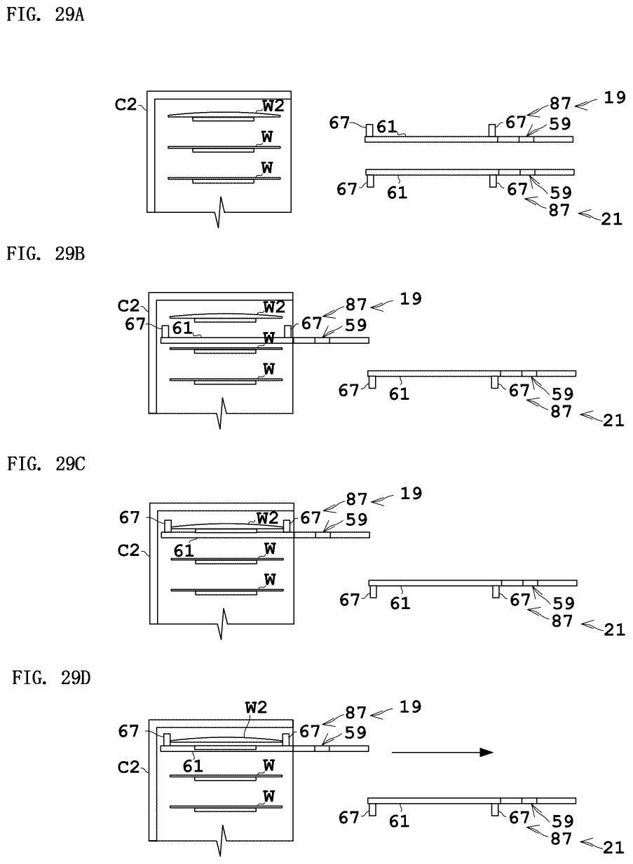

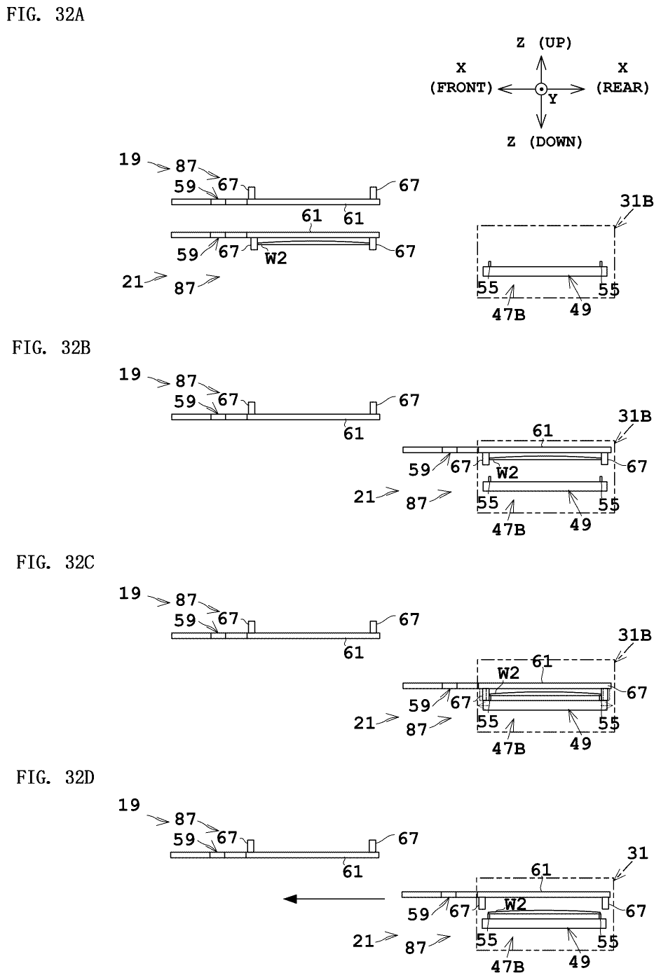

A pattern of the transfer operation of the substrate W by the indexer robot IR in the substrate processing apparatus 1 will be described with reference to FIGS. 24 to 32D. FIG. 24 is a diagram illustrating four transfer patterns. FIGS. 25A to 25D, 26A to 26D, 27A to 27D, and 28A to 28D are diagrams for explaining the operation of a first transfer pattern PT1. FIGS. 29A to 29D, 30A to 30D, 31A to 31D, and 32A to 32D are diagrams for explaining the operation of a second transfer pattern PT2. The operation of a third transfer pattern PT3 will be described with reference to FIGS. 25A to 25D and 32A to 32D. The operation of a fourth transfer pattern PT4 will be described with reference to FIGS. 29A to 29D and 28A to 28D.

### <Four Transfer Patterns>

FIG. 24 will be referred to. In FIG. 24 and subsequent drawings, the delivery part 15 is illustrated as a view of the inside as viewed in the width direction Y.

In the substrate processing apparatus 1 according to the present embodiment, a plurality of processing units 31A, 31B, and 31C having different modes of the hand (hereinafter, referred to as a loading/unloading mode) used for loading and unloading the substrates W are mounted in a mixed manner.

The substrate processing apparatus of the present embodiment is roughly divided into two types of transfer patterns according to the loading/unloading mode in the carrier C and the loading/unloading mode in the processing unit 31.

The first transfer pattern is the first transfer pattern PT1 and the second transfer pattern PT2 which are adopted in a case where the loading/unloading mode in the carrier C is different from the loading/unloading mode in the processing unit 31. In these transfer patterns, the substrate W unloaded from the carrier C is temporarily placed in the delivery part 15. The hand is replaced while the substrate W is placed in the delivery part 15. The substrate W is loaded into the processing unit 31 by the replaced hand. The delivery part 15 corresponds to a “temporary placement part” in the present invention.

Specifically, in the first transfer pattern PT1, the loading/unloading mode in the carrier C is the second hand 21 (upper holding hand), and the loading/unloading mode in the processing unit 31 is the first hand 19 (lower holding hand). In the second transfer pattern PT2, the loading/unloading mode in the carrier C is the first hand 19 (lower holding hand), and the loading/unloading mode in the processing unit 31 is the second hand 21 (upper holding hand).

The second transfer pattern is the third transfer pattern PT3 and the fourth transfer pattern PT4 which are adopted in a case where the loading/unloading mode in the carrier C and the loading/unloading mode in the processing unit 31 are the same. In these transfer patterns, in a case where the processing unit 31 can receive the substrate W at the time of unloading the substrate W from the carrier C, the substrate W is directly loaded into the processing unit 31.

Specifically, in the third transfer pattern PT3, the loading/unloading mode in the carrier C and the loading/unloading mode in the processing unit 31 are the second hand 21 (upper holding hand). In the fourth transfer pattern PT4, the loading/unloading mode in the carrier C and the loading/unloading mode in the processing unit 31 are the first hand 19 (lower holding hand).

An example of how to determine the loading/unloading mode with the carrier C according to the shape of the substrate W will be described. In a case where the substrate W has a ball shape having a downwardly convex center, it is preferable to transfer the substrate W using the second hand 21 (upper holding hand). Therefore, the substrate W of a ball shape having a downwardly convex center is transferred using the second hand 21. In a case where the substrate W has an umbrella shape having an upwardly convex center, it is preferable to transfer the substrate W using the first hand 19 (lower holding hand). Therefore, the substrate W of an umbrella shape having an upwardly convex center is transferred using the first hand 19. However, this does not mean that the first hand 19 cannot transfer the substrate W of a ball shape having a downwardly convex center. This does not mean that the second hand 21 cannot transfer the substrate W of an umbrella shape having an upwardly convex center.

In a case where the substrate W is a substrate having no warpage (or small warpage), either the first hand 19 or the second hand 21 may be used. In a case where either the first hand 19 or the second hand 21 may be used, which one of the first hand 19 and the second hand 21 is used is determined in consideration of gap information in the carrier C.

The control unit CU selects the carrier C and the loading/unloading mode in the processing unit 31 on the basis of the shape information of the substrate W and the processing condition information of the substrate W described above.

In any transfer pattern, in a case where the processing unit 31 cannot receive the substrate W at the time when the substrate W is unloaded from the carrier C, the substrate W may be placed in the delivery part 15 to stand by until the substrate W can be received.

### <First Transfer Pattern PT1>

The transfer of the substrate W according to the first transfer pattern PT1 will be described.

In this example, a substrate W1 having a downwardly convex center is placed in the uppermost stage of the carrier C1.

FIGS. 25A to 25D will be referred to. The substrate W1 of a ball shape having a downwardly convex center is placed in the uppermost stage of the carrier C1. The indexer robot IR transfers the substrate W1. The ball shape having a downwardly convex center is shape information of the substrate W1. Therefore, the substrate W1 is clamped by the guide 67 of the second hand 21 (upper holding hand).

Note that the loading/unloading mode in the carrier C1 may not be selected on the basis of the substrate information of the substrate W1. For example, it is gap information between the uppermost shelf of the carrier C1 and the ceiling. In the carrier C1, the vertical width of the gap from the uppermost shelf to the ceiling is sufficiently wider than the widths DP of the first hand 19 and the second hand 21. Therefore, in the substrate W1 placed in the uppermost stage of the carrier C2, the second hand 21 may be selected on the basis of the gap information of the carrier C1 as long as the warpage of the substrate W1 is small.

As illustrated in FIG. 25A, the control unit CU moves the second hand 21 to a height for unloading the substrate W1 in front of the opening of the carrier C1. As illustrated in FIG. 25B, the second hand 21 is inserted into the insertion position in the carrier C1 at this height. As illustrated in FIG. 25C, the second hand 21 descends from the insertion position to the clamp position for clamping the substrate W1 with the guide 67, and clamps the substrate W1 with the guide 67 at the clamp position. As illustrated in FIG. 25D, the second hand 21 lifts the substrate W1 clamped by the guide 67 to a height for unloading the substrate W1 from the carrier C1, and unloads the substrate W1 from the carrier C1.

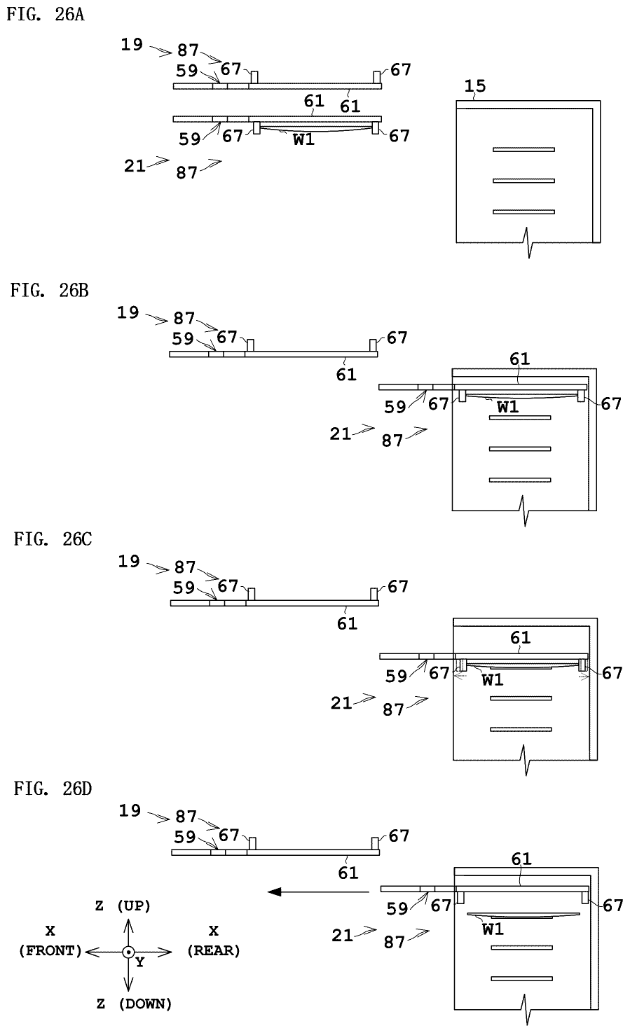

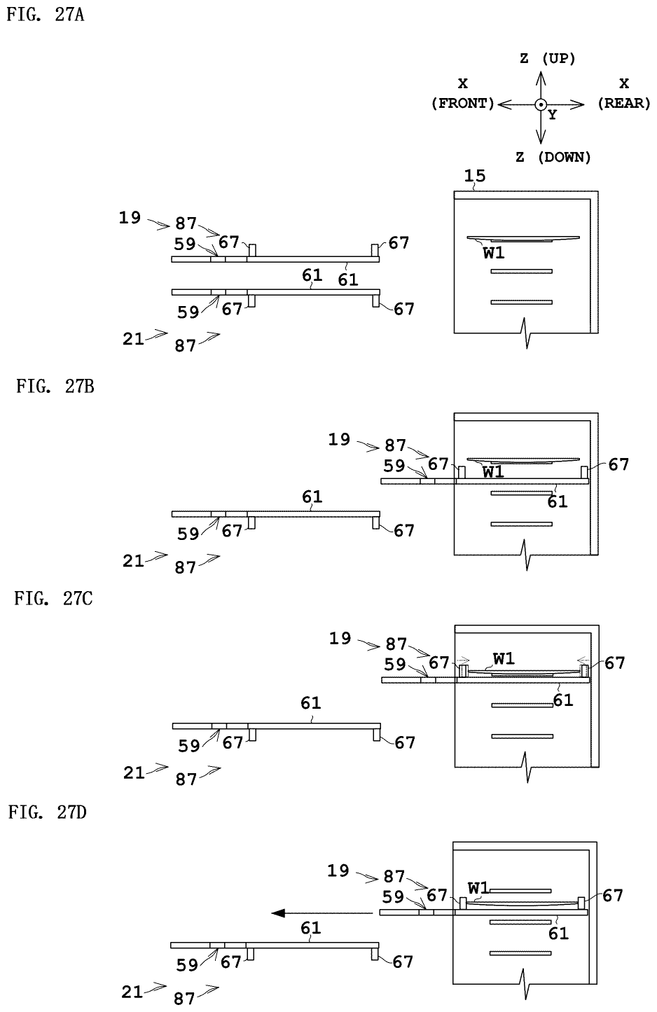

FIGS. 26A to 26D and 27A to 27D will be referred to. It is determined that the substrate W1 is loaded into the processing unit 31C on the basis of the processing condition information.

In the present example, the loading/unloading mode in the carrier C1 is the second hand 21 (upper holding hand), and the loading/unloading mode in the processing unit 31C is the first hand 19 (lower holding hand). Therefore, the substrate W1 held by the second hand 21 is once placed in the delivery part 15. Meanwhile, the second hand 21 is replaced with the first hand 19. The first hand 19 holds the substrate W1 and transfers the substrate W1 to the processing unit 31.

First, as illustrated in FIG. 26A, the control unit CU moves the second hand 21 to a height for loading the substrate W1 in front of the opening of the delivery part 15. As illustrated in FIG. 26B, the second hand 21 is inserted into the insertion position of the delivery part 15 at this height. As illustrated in FIG. 26C, the second hand 21 descends from the insertion position to the placement position for placing the substrate W1, and opens the guide 67 that clamps the substrate W1 at the placement position. As illustrated in FIG. 26D, the second hand 21 with the guide 67 opened is lifted to a height for unloading from the delivery part 15, and is retracted from the delivery part 15.

Next, as illustrated in FIG. 27A, the control unit CU moves the first hand 19 to a height for unloading the substrate W1 in front of the opening of the delivery part 15. As illustrated in FIG. 27B, the first hand 19 is inserted into the insertion position of the delivery part 15 at this height. As illustrated in FIG. 27C, the first hand 19 is raised from the insertion position to the clamp position for clamping the substrate W1 with the guide 67, and clamps the substrate W1 with the guide 67 at the clamp position. As illustrated in FIG. 27D, the first hand 19 moves the substrate W1 clamped by the guide 67 to a height for unloading the substrate W1 from the delivery part 15, and unloads the substrate W1 from the delivery part 15.

As described above, it is preferable to transfer the substrate W1 of a ball shape having a downward convex center using the second hand 21 (upper holding hand). However, like the second hand 21, the first hand 19 (lower holding hand) can clamp the outer peripheral surface of the substrate W1 between the guides 67 and adjust the biasing force of each guide 67 to the outer peripheral surface of the substrate W. Therefore, even if the second hand 21 is changed to the first hand 19, the substrate W1 can be appropriately held.

Next, as illustrated in FIG. 28A, the control unit CU moves the first hand 19 to a height for loading the substrate W1 in front of the opening of the processing unit 31C. As illustrated in FIG. 28B, the first hand 19 is inserted into the insertion position of the processing unit 31C at this height. As illustrated in FIG. 28C, the first hand 19 is lowered downward in the up-down direction Z to a position where the substrate W1 clamped by the guide 67 comes into contact with the placement part 47C. The lowering of the first hand 19 is stopped, the guide 67 is opened, and the substrate W1 is delivered to the placement part 47C. As illustrated in FIG. 28D, the first hand 19 is removed from the processing unit 31C.

### <Second Transfer Pattern PT2>

The transfer of the substrate W according to the second transfer pattern PT2 will be described.

In this example, a substrate W2 having an upwardly convex center is placed in the uppermost stage of the carrier C2.

FIGS. 29A to 29D will be referred to. The substrate W2 of an umbrella shape having an upwardly convex center is placed in the uppermost stage of the carrier C2. The indexer robot IR transfers the substrate W2. The ball shape having an upwardly convex center is shape information of the substrate W2. Therefore, the substrate W2 is clamped by the guide 67 of the first hand 19 (lower holding hand).

Note that the loading/unloading mode in the carrier C2 may not be selected on the basis of the substrate information of the substrate W2. In the carrier C2, the vertical width of the gap from the uppermost shelf to the ceiling is narrower than that of the carrier C1. The vertical width is smaller than the thickness of the first hand 19 and the second hand 21. Therefore, the substrate W2 placed in the uppermost stage of the carrier C2 is unloaded from the carrier C2 by the first hand 19 even if the warpage of the substrate W2 is small.

As illustrated in FIG. 29A, the control unit CU moves the first hand 19 to a height for unloading the substrate W2 in front of the opening of the carrier C2. As illustrated in FIG. 29B, the first hand 19 is inserted into the insertion position of the carrier C2 at this height. As illustrated in FIG. 29C, the first hand 19 is raised from the insertion position to a clamp position for clamping the substrate W2 with the guide 67, and clamps the substrate W2 with the guide 67 at the clamp position. As illustrated in FIG. 29D, the first hand 19 lifts the substrate W2 clamped by the guide 67 to a height for unloading the substrate W2 from the carrier C2, and unloads the substrate W2 from the carrier C2.

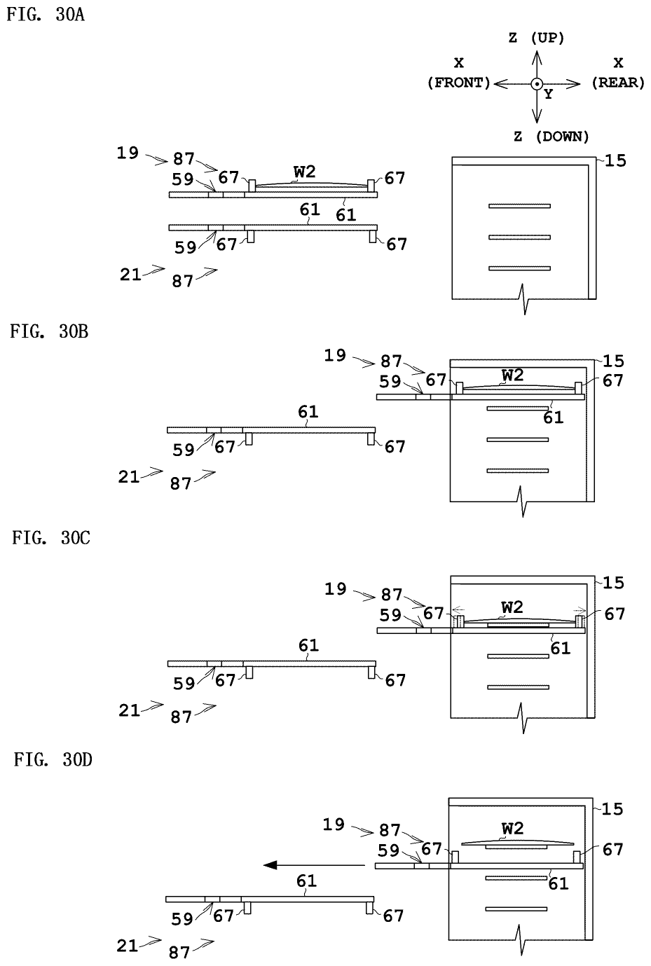

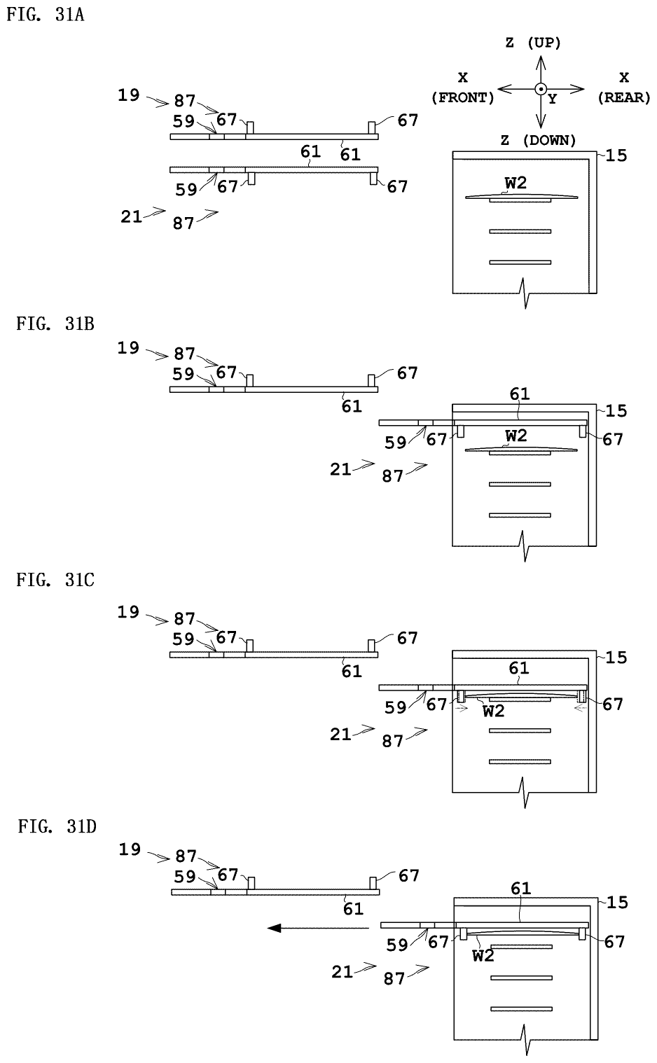

FIGS. 30A to 30D and 31A to 31D will be referred to. It is determined that the substrate W2 is loaded into the processing unit 31B on the basis of the processing condition information.

In the present example, the loading/unloading mode in the carrier C2 is the first hand 19 (lower holding hand), and the loading/unloading mode in the processing unit 31B is the second hand 21 (upper holding hand). Therefore, the substrate W2 held by the first hand 19 is once placed in the delivery part 15. Meanwhile, the first hand 19 is replaced with the second hand 21. The second hand 21 holds the substrate W2 and transfers the substrate W2 to the processing unit 31B.

First, as illustrated in FIG. 30A, the control unit CU moves the first hand 19 to a height for loading the substrate W2 in front of the opening of the delivery part 15. As illustrated in FIG. 30B, the first hand 19 is inserted into the insertion position of the delivery part 15 at this height. As illustrated in FIG. 30C, the first hand 19 descends from the insertion position to the placement position for placing the substrate W2, and opens the guide 67 that clamps the substrate W2 at the placement position. As illustrated in FIG. 30D, the first hand 19 with the guide 67 opened is lowered to a height for unloading the first hand from the delivery part 15, and is retracted from the delivery part 15.

Next, as illustrated in FIG. 31A, the control unit CU moves the second hand 21 to a height for unloading the substrate W2 in front of the opening of the delivery part 15. As illustrated in FIG. 31B, the second hand 21 is inserted into the insertion position of the delivery part 15 at this height. As illustrated in FIG. 31C, the second hand 21 descends from the insertion position to the clamp position for clamping the substrate W2 with the guide 67, and clamps the substrate W2 with the guide 67 at the clamp position. As illustrated in FIG. 31D, the second hand 21 lifts the substrate W2 clamped by the guide 67 to a height for unloading the substrate W2 from the delivery part 15, and unloads the substrate W2 from the delivery part 15.

Next, as illustrated in FIG. 32A, the control unit CU moves the second hand 21 to a height for loading the substrate W2 in front of the opening of the processing unit 31B. As illustrated in FIG. 32B, the second hand 21 is inserted into the insertion position of the processing unit 31B at this height. As illustrated in FIG. 32C, the second hand 21 is lowered downward in the up-down direction Z to a position where the substrate W1 clamped by the guide 67 comes into contact with the support pin 55 of the placement part 47C. At a position where the substrate W1 clamped by the guide 67 comes into contact with the support pin 55, the lowering of the second hand 21 is stopped, the guide 67 is opened, and the substrate W2 is delivered to the support pin 55. As illustrated in FIG. 32D, the second hand 21 is removed from the processing unit 31B.

As described above, in either the first transfer pattern PT1 or the second transfer pattern PT2, when the substrate W is unloaded from the carrier C, an optimum hand can be selected according to the shape information of the substrate W (the loading/unloading mode in the carrier C). In addition, when the substrate W is loaded into the processing unit 31, an optimum hand can be selected according to the loading/unloading mode in the processing unit 31. In addition, in a case where the loading/unloading mode in the carrier C is different from the loading/unloading mode in the processing unit 31, the loading/unloading mode in the carrier C can be replaced with the loading/unloading mode in the processing unit 31. Even with the replaced hand, the substrate W can be appropriately transferred to the processing unit 31.

### <Third Transfer Pattern PT3>

The transfer of the substrate W according to the third transfer pattern PT3 will be described. The third transfer pattern PT3 is the same as the first transfer pattern PT1 and the second transfer pattern PT2 described above with reference to FIGS. 25A to 25D and 32A to 32D. That is, since the loading/unloading mode in the carrier C1 is the same as the loading/unloading mode in the processing unit 31B, the substrate W1 is transferred using the loading/unloading mode in the carrier C1 as it is in the loading/unloading mode in the processing unit 31B. That is, the substrate W1 can be unloaded from the carrier C1 and the substrate W1 can be loaded into the processing unit 31B with the second hand 21.

### <Fourth Transfer Pattern PT4>

The transfer of the substrate W according to the fourth transfer pattern PT4 will be described. The fourth transfer pattern PT4 is the same as the first transfer pattern PT1 and the second transfer pattern PT2 described above with reference to FIGS. 29A to 29D and 28A to 28D. That is, since the loading/unloading mode in the carrier C2 is the same as the loading/unloading mode in the processing unit 31C, the substrate W2 is transferred using the loading/unloading mode in the carrier C2 as it is as the loading/unloading mode in the processing unit 31C. That is, the substrate W2 can be unloaded from the carrier C2 and the substrate W2 can be loaded into the processing unit 31C with the first hand 19.

According to the first embodiment, when the substrate W is held by the first hand 19, the control unit CU operates the servomotor 79 to move each guide 67 to the outer peripheral surface of the substrate W. In a case where the tactile sensor 73 detects that each guide 67 abuts on the outer peripheral surface of the substrate W, the control unit CU adjusts the biasing force of each guide 67 to the outer peripheral surface of the substrate W by the servomotor 79 according to the shape of the substrate W. Therefore, the clamping force can be adjusted for each shape of the substrate W such as warpage and thickness of the substrate W. As a result, in a case where the first hand 19 and the second hand 21 are replaced, it is possible to prevent the substrate W from being damaged at the time of transfer regardless of the shape of the substrate W even if the hand is replaced. It is also possible to prevent each guide 67 from being damaged.

In the first embodiment, all the guides 67 are movable, and the biasing force is adjusted for all the three guides 67. Therefore, when the substrate W is clamped, the distance by which the lower surface of the substrate W is rubbed in the horizontal direction at the place where the substrate W is placed can be shortened. As a result, in a case where the first hand 19 and the second hand 21 are replaced, even in a case where the center of the substrate W at the position where the substrate W is placed is deviated from the center of the hand at the delivery position where the hand has advanced in the hands before and after the replacement, the movement of the center position of the substrate W at the time of clamping the substrate W is minimized. Therefore, it is possible to suppress particles generated as the substrate W is clamped.

The correspondence between the above-described first embodiment and the configuration of the present invention is as follows.

The indexer robot IR corresponds to a “substrate transfer apparatus” in the present invention. The first hand 19 (lower holding hand) and the second hand 21 (upper holding hand) correspond to “hands” in the present invention. The horizontal drive mechanism 57 corresponds to a “horizontal drive mechanism” in the present invention. Each guide 67 corresponds to a “movable guide” in the present invention. The movable piece 71, the servomotor 79, and the ball screw 83 correspond to an “advancing/retracting drive mechanism” in the present invention. The pusher arm 89, the servomotor 79, and the ball screw 83 also correspond to the “advancing/retracting drive mechanism” in the present invention. The control unit CU corresponds to a “control unit” in the present invention. The processing unit 31 including the processing units 31A, 31B, and 31C corresponds to a “processing unit” in the present invention.

The present invention is not limited to the above embodiment, and can be modified as follows.

(1) In the embodiment described above, the guide 67 provided on the first hand 19 and the guide 67 provided on the second hand 21 have the same shape, but may have different shapes.

(2) In the first embodiment described above, the tactile sensor 73 is employed as an outer peripheral surface detector. However, the present invention is not limited to such a configuration. That is, as long as it can be detected that the guide 67 abuts on the outer peripheral surface of the substrate W, another detector may be adopted. As the outer peripheral surface detector, for example, a proximity sensor, a reflective sensor, or the like may be adopted.

(3) In the first embodiment described above, the tactile sensor 73 is provided at a portion where the hand 67 is attached to the finger portion 61. However, the present invention is not limited to such an embodiment. That is, the tactile sensor 73 may be provided on the side surface of the guide 67. In this case, the detection surface 75 is preferably directed toward the outer peripheral surface side of the substrate W. This is because the detection sensitivity of the tactile sensor 73 can be increased.

(4) In the first embodiment described above, the guide 67 has a columnar shape, but the present invention is not limited to such an embodiment. That is, the shape of the guide 67 is not limited.

(5) In the first embodiment described above, the indexer robot IR is configured to be able to independently move the first hand 19 and the second hand 21 in the front-rear direction X, the width direction Y, the up-down direction Z, and the like, but may be configured not to be able to independently move the first hand 19 and the second hand 21. That is, the first hand 19 and the second hand 21 share a drive unit that moves in the front-rear direction X, the width direction Y, the up-down direction Z, and the like. The horizontal drive mechanism 57 and the configuration corresponding to the “advancing/retracting drive mechanism” in the present invention are independent of each other.

(6) In the first embodiment described above, a configuration including three guides 67 is adopted. However, the present invention is not limited to such a configuration. That is, the present invention may be configured to include two guides 67. In this case, in order to stably hold the substrate W, the guide 67 on the distal end side in the front-rear direction X is preferably formed to be wider along the width direction Y than the guide 67 (pusher) on the proximal end side.

(7) In the first embodiment described above, a configuration in which all the three guides 67 are movable is adopted. However, the present invention is not limited to such a configuration. That is, the present invention may be configured such that at least one guide 67 is movable.

(8) In the first embodiment described above, a configuration including three guides 67 is adopted. However, the present invention is not limited to such a configuration. That is, the present invention may be configured to include four or more guides 67.

(9) In the first embodiment described above, the advancing/retracting drive mechanism is configured to move the guide 67 with the movable piece 71, the servomotor 79, and the ball screw 83. However, the present invention is not limited to such a configuration. For example, a configuration including a wire having one end side connected to a spring, a guide fixedly attached to a part of the wire, and a drive unit that winds the other end side of the wire to move the wire in the front-rear direction X may be adopted.

(10) In the first embodiment described above, the guide 67 is driven to advance and retract in the front-rear direction X with respect to the finger portion 61, but the present invention is not limited to such a configuration. For example, the guide 67 may be fixedly attached to the finger portion 61, and the finger portion 61 may be attached to the finger attachment section 65 so as to be movable forward and backward in the front-rear direction X in the finger attachment section 65. As a result, the movable portion can be disposed outside the outer peripheral surface of the substrate W, which is advantageous in terms of cleanliness.

(11) In the first embodiment described above, the first hand 19 includes the tactile sensor 73, but the first hand 19 may not include the tactile sensor 73. This will be described with reference to FIG. 12 described above.

The clamping control unit 97 operates the servomotor 79 according to the position information from the encoder 81. The clamping control unit 97 can detect the drive current supplied to the servomotor 79 as drive current information. The clamping control unit 97 determines that the guide 67 abuts on the outer peripheral surface of the substrate W on the basis of one or both of the position information and the drive current information.

That is, when the guide 67 abuts on the outer peripheral surface of the substrate W, the movement of the guide 67 is temporarily hindered. Therefore, the displacement of the position information from the encoder 81 temporarily stops. Even if the guide 67 abuts on the outer peripheral edge of the substrate, it is necessary to increase the torque of the servomotor 79 in order to further move the guide 67 toward the outer peripheral surface of the substrate W. Therefore, the drive current to the servomotor 79 increases, and the drive current information is displaced. Therefore, by monitoring one or both of the position information and the drive current information, it is possible to accurately determine that the guide 67 abuts on the outer peripheral surface of the substrate W. After the guide 67 abuts on the outer peripheral surface of the substrate W, the clamping control unit 97 adjusts the biasing force of the guide 67 to the outer peripheral surface of the substrate W according to the shape information from the shape information storage unit 93 to clamp the substrate W.

As described above, the control unit CU determines that the guide 67 abuts on the outer peripheral surface of the substrate W on the basis of at least one of the drive current information from the clamping control unit 97 and the position information from the encoder 81. Therefore, it is not necessary to provide the tactile sensor 73 or the like to detect whether the guide 67 abuts on the outer peripheral surface of the substrate W. As a result, the structure can be simplified, and the cost can be suppressed.

### Second Embodiment

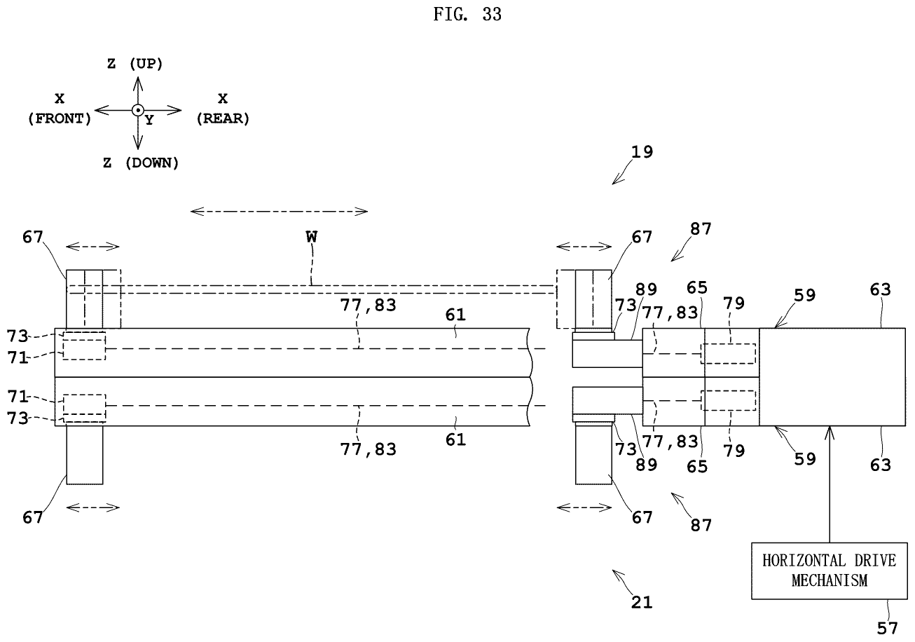

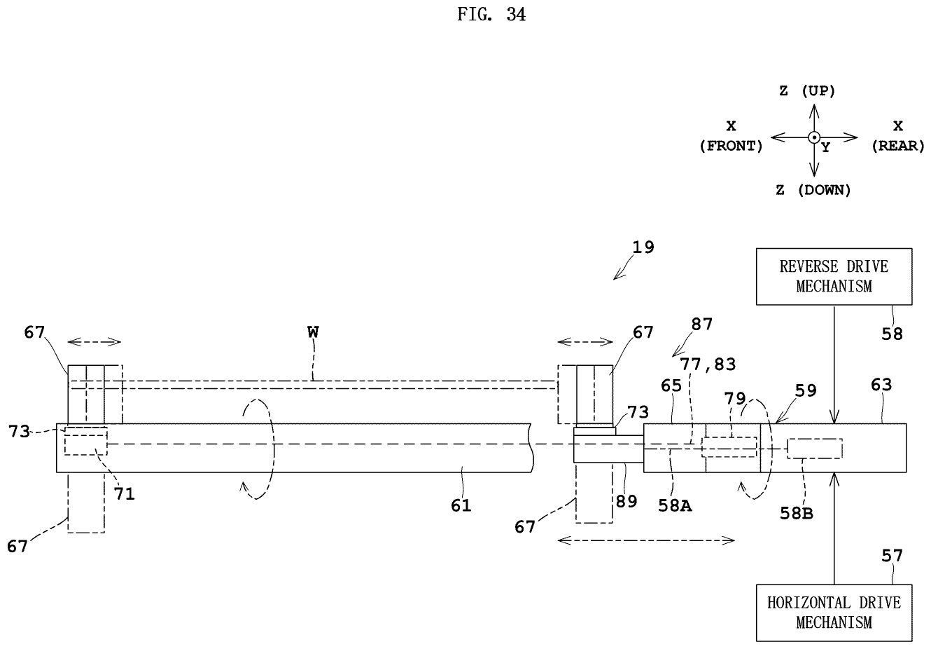

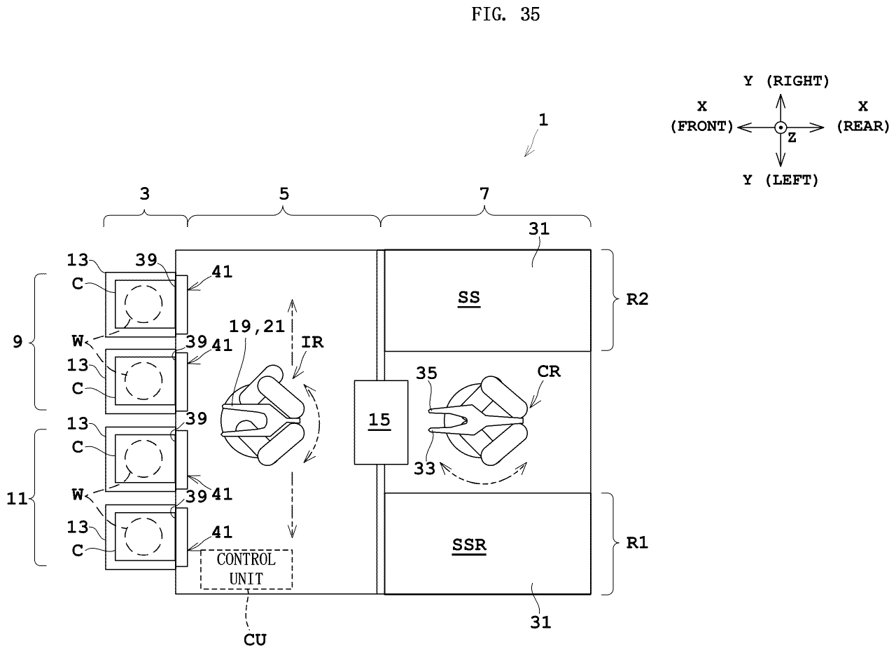

Next, a second embodiment of the present invention will be described with reference to FIG. 33.

FIG. 33 is a side view of the hand in the substrate processing apparatus according to the second embodiment. Note that the configuration and the like of the substrate processing apparatus 1 are similar to those of the first embodiment described above except for the points described below.

In the substrate processing apparatus 1 of the first embodiment, the first hand 19 had only a lower holding function, and the second hand 21 had only an upper holding function. However, in the substrate processing apparatus 1, one hand may have both the lower holding and upper holding functions. The substrate processing apparatus 1 according to the second embodiment includes a double-sided hand 22 in which an upper surface side of one hand has the lower holding function and a lower surface side of one hand has the upper holding function.

That is, the double-sided hand 22 includes a guide 67a on the upper surface side of one hand and a guide 67b on the lower surface side of one hand. Specifically, the guide 67a is provided on the upper surface of the movable piece 71 and the upper surface of the pusher arm 89. The guide 67b is provided on the lower surface of the movable piece 71 and the lower surface of the pusher arm 89. As described above, in the double-sided hand 22, the guide 67a for the lower holding and the guide 67b for the upper holding are shared by one hand.

The double-sided hand 22 shares the configurations of the movable piece 71 corresponding to the “advancing/retracting drive mechanism” of the present invention, the servomotor 79, the ball screw 83, and the configurations of the pusher arm 89, the servomotor 79, and the ball screw 83. The configurations of the movable piece 71, the servomotor 79, and the ball screw 83, and the configurations of the pusher arm 89, the servomotor 79, and the ball screw 83 are shared by the lower holding and the upper holding. In addition, a mechanism for moving the indexer robot IR in the front-rear direction X, the width direction Y, the up-down direction Z, and the like is also shared between the lower holding and the upper holding. That is, the guides 67a and 67b are configured to move simultaneously and in the same direction in accordance with the movement of the movable piece 71.

The force applied to the guide 67a is detected by a tactile sensor 73a provided on the upper surface of the movable piece 71. The force applied to the guide 67b is detected by a tactile sensor 73b provided on the lower surface of the movable piece 71.

As described above, the double-sided hand 22 is one hand common to the guide 67a for the lower holding and the guide 67b for the upper holding. Therefore, the double-sided hand 22 can reduce the thickness of the hand as compared with a configuration in which the first hand 19 (lower holding hand) and the second hand 21 (upper holding hand) are overlapped.

Thus, when the hand is replaced, the hand can be replaced by retracting the hand in the backward direction X, moving the hand in the upward direction Z or the downward direction Z according to the surface to be used next, and advancing the hand in the forward direction Z again. That is, in the first embodiment, in a case where the hand is replaced, it is necessary to separate a sufficient distance in order to avoid a collision between the hands, particularly between the arms supporting the hand. In the second embodiment, such necessity is eliminated. Therefore, the time for replacing the hand can be shortened.

### Third Embodiment

Hereinafter, a third embodiment of the present invention will be described with reference to FIG. 34.

FIG. 34 is a side view of the hand in the substrate processing apparatus according to the third embodiment. Note that the configuration and the like of the substrate processing apparatus 1 are similar to those of the first embodiment described above. Therefore, a detailed description of the substrate processing apparatus 1 will be omitted.

In the substrate processing apparatus 1 of the third embodiment, only the first hand 19 is configured on the upper surface side of one hand. However, the indexer robot IR includes a reverse drive mechanism 58 in addition to the horizontal drive mechanism 57. The reverse drive mechanism 58 is a mechanism that rotates the first hand 19 by 180 degrees. For example, in a case where the reverse drive mechanism 58 is provided at the attachment proximal end section 63, the rotation from the attachment proximal end section 63 to the tip of the finger portion 61 is 180 degrees. That is, the guide 67 also rotates by 180 degrees. In the drawing, the reversed guide 67 is indicated by a one-dot chain line. The reverse drive mechanism 58 includes, for example, a rotation shaft portion 58A provided from the attachment proximal end section 63 to the finger attachment section 65, and a rotation drive portion 58B that rotates the rotation shaft portion 58A at the attachment proximal end section 63. The rotation shaft portion 58A is, for example, a rotation shaft to which a gear is attached on the proximal end side. The rotation drive portion 58B includes, for example, a gear and a motor. The gear of the rotation shaft portion 58A meshes with the gear of the rotation drive portion 58B, and the motor rotates the gear of the rotation drive portion 58B. As a result, the rotation shaft portion 58A rotates. In this manner, only one first hand 19 serves as both the lower holding hand and the upper holding hand.

Accordingly, when the hand is replaced, the hand can be replaced by retracting the hand in the backward direction X and reversing the hand. That is, in the second embodiment, it is not necessary to avoid buffering between the arms when replacing the hands, but it is necessary to provide two types of hands, the first hand 19 and the second hand 21. On the other hand, in the third embodiment, the same effect as that of the second embodiment can be realized only by the first hand 19. Therefore, it is possible to realize the substrate processing apparatus 1 more compact than that of the second embodiment.

### Fourth Embodiment

Next, a fourth embodiment of the present invention will be described with reference to FIGS. 35, 36, and 37.

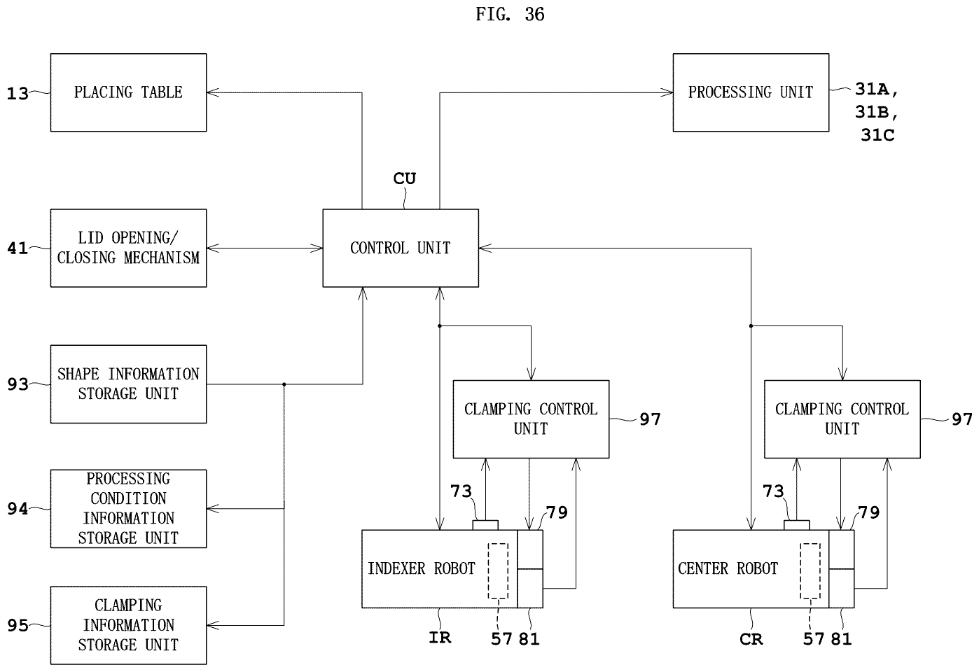

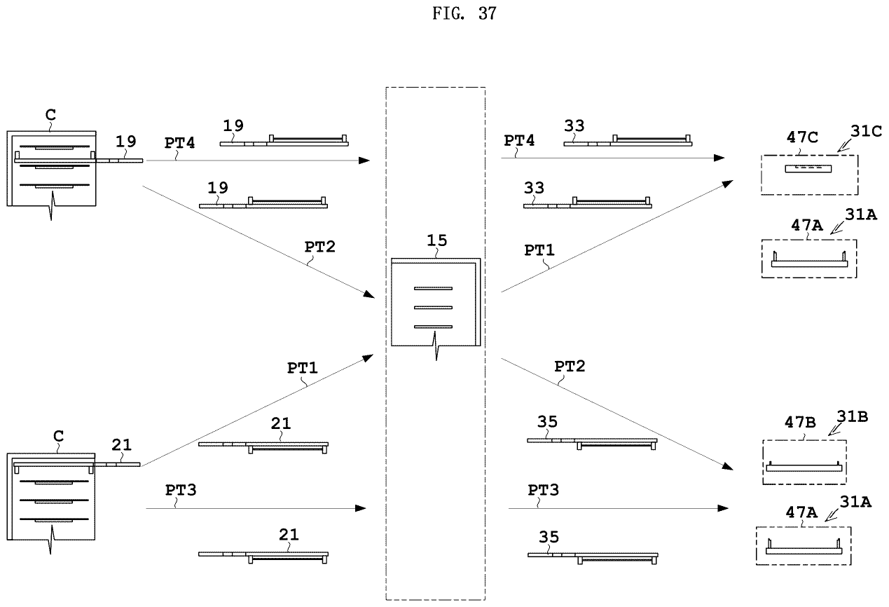

FIG. 35 is a plan view illustrating a schematic configuration of a substrate processing apparatus according to the fourth embodiment. FIG. 36 is a block diagram illustrating a control system. FIG. 37 is a diagram for explaining an operation related to transfer. Note that the configuration and the like of the substrate processing apparatus 1 are similar to those of the first embodiment except for the following points. Therefore, a detailed description of the substrate processing apparatus 1 will be omitted.

The substrate processing apparatus 1 according to the fourth embodiment includes a center robot CR in addition to the indexer robot IR. The delivery part 15 is disposed between the indexer block 5 and the processing block 7. Therefore, the indexer robot IR transfers the substrate W between the carrier C placed on the transfer table 13 and the delivery part 15, and the center robot CR transfers the substrate W between the delivery part 15 and the processing unit 31.

In the fourth embodiment, not only the indexer robot IR but also the center robot CR has the same configuration as the first hand 19 and the second hand 21. That is, the center robot CR includes a first hand 33 corresponding to the first hand 19 and a second hand 35 corresponding to the second hand 21. That is, when the center robot CR transfers the substrate W, the control unit CU selects the loading/unloading mode in the delivery part 15 on the basis of the shape information of the substrate W placed in the delivery part 15, and selects the loading/unloading mode in the processing unit 31 on the basis of the processing condition information of the substrate W placed in the delivery part 15. Even when the center robot CR transfers the substrate W, the shape information of the substrate W is read from the shape information storage unit 93, and the processing condition information of the substrate W is read from the processing condition information storage unit 94.

The shape information of the substrate W and the processing condition information of the substrate W are associated with which shelf of the delivery part 15 the substrate W taken out from which shelf of the carrier C is placed. Therefore, the control unit CU can use the shape information and the processing condition information of the substrate W transferred by the indexer robot IR as the transfer condition in the center robot CR.

With such a configuration, as illustrated in FIG. 37, in the first transfer pattern PT1, the indexer robot IR unloads the substrate W from the carrier C by the optimum hand (second hand 21) according to the shape information of the substrate W, and places the substrate W on the delivery part 15. The center robot CR unloads the substrate W from the delivery part 15 by an optimum hand (first hand 33) corresponding to the processing condition information of the substrate W, and loads the substrate W into the processing unit 31C. In the second transfer pattern PT2, the indexer robot IR unloads the substrate W from the carrier C by an optimum hand (first hand 19) according to the shape information of the substrate W, and places the substrate W on the delivery part 15. The center robot CR unloads the substrate W from the delivery part 15 by an optimum hand (second hand 35) corresponding to the processing condition information of the substrate W, and loads the substrate W into the processing unit 31B.

In the third transfer pattern PT3, the indexer robot IR unloads the substrate W from the carrier C by the optimum hand (second hand 21) according to the shape information of the substrate W, and places the substrate W on the delivery part 15. The center robot CR unloads the substrate W from the delivery part 15 by an optimum hand (second hand 35) corresponding to the processing condition information of the substrate W, and loads the substrate W into the processing unit 31C. In the fourth transfer pattern PT4, the indexer robot IR unloads the substrate W from the carrier C by an optimum hand (first hand 19) according to the shape information of the substrate W, and places the substrate W on the delivery part 15. The center robot CR unloads the substrate W from the delivery part 15 by an optimum hand (first hand 33) corresponding to the processing condition information of the substrate W, and loads the substrate W into the processing unit 31C.

As a result, the substrate W can be efficiently transferred by the indexer robot IR and the center robot CR.

The indexer robot IR and the center robot CR correspond to a “substrate transfer apparatus” in the present invention. Only one of the indexer robot IR and the center robot CR may correspond to the “substrate transfer apparatus” of the present invention.

The present invention is not limited to the above embodiment, and can be modified as follows.

(1) In each of the first to fourth embodiments described above, the configuration of the substrate processing apparatus 1 has been described as an example, but the present invention is not limited to the substrate processing apparatus having such a configuration.

(2) In each of the first to fourth embodiments described above, the case of treating the circular substrate W has been described as an example, but the substrate W is not limited to a circular shape.

(3) In the first embodiment described above, the first hand 19 and the second hand 21 are configured not to be reversed, but the first hand 19 and the second hand 21 may be configured to be reversed. That is, only the first hand 19 can cope with both the upper holding and the lower holding. Only the second hand 21 can cope with both upper holding and lower holding. Thus, the first hand 19 and the second hand 21 can perform different transfer operations in parallel in the substrate processing apparatus 1.

(4) In the second embodiment described above, the hand (double-sided hand 22) including the first hand 19 on the upper surface and the second hand 21 on the lower surface is configured not to be reversed, but the double-sided hand 22 may be configured to be reversed. As a result, in a case where the substrate W is transferred by the lower holding hand, the first hand 19 and the second hand 21 can be used separately. Similarly, the first hand 19 and the second hand 21 can be selectively used in a case where the substrate W is transferred by the upper holding hand.

※ The present invention may be embodied in other specific
forms without departing from the spirit or essential
attributes thereof and, accordingly, reference should be
made to the appended claims, rather than to the foregoing
specification, as indicating the scope of the invention.

What is claimed is:

1. A substrate transfer apparatus for transferring a substrate, the apparatus comprising:
a hand that holds the substrate in a horizontal posture;
a horizontal drive mechanism that advances and retracts the hand in a horizontal plane in order to deliver the substrate;
at least two guides that are provided on the hand and clamp an outer peripheral surface of the substrate to separate and hold the substrate from the hand; and
an advancing/retracting drive mechanism that drives at least one of the at least two guides to advance and retract with respect to the substrate as a movable guide, wherein
the hand has modes for holding the substrate including:
an upper holding in which the hand is positioned above the substrate and the guide clamps an outer peripheral surface of the substrate in a state where the hand and the substrate are separated from each other; and
a lower holding in which the hand is positioned below the substrate, and the guide clamps an outer peripheral surface of the substrate in a state where the hand and the substrate are separated from each other.

2. The substrate transfer apparatus according to claim 1, comprising:
a plurality of the hands, wherein
at least one of the plurality of hands is an upper holding hand in which the guide is provided on a lower surface of the hand, and
at least one of the plurality of hands is a lower holding hand in which the guide is provided on an upper surface of the hand.

3. The substrate transfer apparatus according to claim 2, wherein
the hand of at least one of the upper holding hand and the lower holding hand includes a reverse portion that reverses one surface of the hand on which the guide is provided and an other surface of the hand on which the guide is not provided.

4. The substrate transfer apparatus according to claim 1, wherein
the hand is a double-sided hand in which the guide is provided on both an upper surface and a lower surface of the hand.

5. The substrate transfer apparatus according to claim 4, wherein
the double-sided hand includes a reverse portion that reverses the upper surface and the lower surface of the double-sided hand.

6. The substrate transfer apparatus according to claim 1, wherein
the hand includes the guide on one of an upper surface and a lower surface of the hand, and
the hand includes a reverse portion that reverses one surface on which the guide is provided and an other surface on which the guide is not provided.

7. A substrate processing apparatus, comprising:
a substrate transfer apparatus that transfers a substrate;
a control unit that controls the substrate transfer apparatus;
a carrier placement part on which a carrier capable of housing a plurality of substrates stacked with a gap is placed;
a temporary placement part on which the substrate unloaded from the carrier placement part is temporarily placed before being loaded into the processing unit; and
a processing unit that performs predetermined processing on the substrate loaded from the carrier or the temporary placement part, wherein
the substrate transfer apparatus includes:
a hand that holds the substrate in a horizontal posture;
a horizontal drive mechanism that advances and retracts the hand in a horizontal plane in order to deliver the substrate;
at least two guides that are provided on the hand and clamp an outer peripheral surface of the substrate to separate and hold the substrate from the hand; and
an advancing/retracting drive mechanism that drives at least one of the at least two guides to advance and retract with respect to the substrate as a movable guide, and
the hand has modes for holding the substrate including:
an upper holding in which the hand is positioned above the substrate and the guide clamps an outer peripheral surface of the substrate in a state where the hand and the substrate are separated from each other; and
a lower holding in which the hand is positioned below the substrate, and the guide clamps an outer peripheral surface of the substrate in a state where the hand and the substrate are separated from each other.

8. The substrate processing apparatus according to claim 7, wherein
the control unit selects either the upper holding or the lower holding with respect to a mode of the hand to be inserted into the carrier or the temporary placement part according to a shape of the carrier or the substrate accommodated in the carrier or the temporary placement part.

9. The substrate processing apparatus according to claim 7, wherein
the control unit selects either the upper holding or the lower holding with respect to a mode of the hand to be inserted into the carrier or the temporary placement part according to gap information between the substrates placed in the carrier or the temporary placement part.

10. The substrate processing apparatus according to claim 9, wherein
the control unit selects one of the upper holding and the lower holding with respect to a mode of the hand to be inserted into the carrier or the temporary placement part according to gap information formed at an uppermost portion in the carrier or the temporary placement part.

11. The substrate processing apparatus according to claim 7, wherein
the processing unit has at least two types of a first processing unit, a second processing unit, and a third processing unit,
the first processing unit has the upper holding as a mode of the hand in which a substrate is loaded and unloaded,
the second processing unit has the lower holding as a mode of the hand in which a substrate is loaded and unloaded,
the third processing unit has both the upper holding and the lower holding as a mode of the hand in which a substrate is loaded and unloaded, and
the control unit selects a mode of the hand according to a type of the processing unit.

12. The substrate processing apparatus according to claim 7, wherein
a mode of the hand when a substrate is loaded and unloaded is the upper holding or the lower holding, and
the control unit changes a mode of the hand in which a substrate has been unloaded from the carrier or the temporary placement part according to a mode of the hand when the substrate is loaded into the processing unit.

13. The substrate processing apparatus according to claim 12, wherein
the control unit changes a mode of the hand in which a substrate has been unloaded from the carrier in accordance with a mode of the hand in which a substrate is loaded into the processing unit in a state where a substrate unloaded from the carrier is temporarily placed in the temporary placement part.

14. The substrate processing apparatus according to claim 13, wherein
the control unit changes the upper holding hand to the lower holding hand or changes the lower holding hand to the upper holding hand.

15. The substrate processing apparatus according to claim 13, wherein
the control unit changes a surface for holding a substrate from the upper surface to the lower surface, or changes a surface for holding a substrate from the lower surface to the upper surface.

16. The substrate processing apparatus according to claim 12, wherein
the control unit changes a mode of the hand in which the substrate has been unloaded from the carrier or the temporary placement part in a state where the hand holds the substrate according to a mode of the hand in which the substrate is loaded into the processing unit.

17. The substrate processing apparatus according to claim 16, wherein
the control unit changes a mode of the hand by controlling a reverse portion that reverses one surface on which the guide is provided and an other surface on which the guide is not provided.

18. The substrate processing apparatus according to claim 12, wherein
the control unit does not perform the change in a case where a mode of the hand in which a substrate has been unloaded from the carrier or the temporary placement part is a same as a mode of the hand in which the substrate is loaded into the processing unit.

19. The substrate processing apparatus according to claim 7, wherein
the substrate transfer apparatus can transfer the substrate placed in the carrier to one of the processing unit and the temporary placement part.

20. The substrate processing apparatus according to claim 7, wherein
the substrate transfer apparatus loads the substrate unloaded from the carrier into the temporary placement part.

21. The substrate processing apparatus according to claim 7, wherein
the substrate transfer apparatus transfers the substrate unloaded from the temporary placement part to the processing unit.
